(19) United States
(12) Patent Application Publication
(10) Pub. No.: US 2025/0386489 A1
(43) Pub. Date: Dec. 18, 2025

(54) THREE-DIMENSIONAL SEMICONDUCTOR DEVICE AND METHOD OF FABRICATING THE SAME

(71) Applicant: Samsung Electronics Co., Ltd., Suwon-si (KR)

(72) Inventors: Yangdoo Kim, Suwon-si (KR); Chanmin Kang, Suwon-si (KR); Gwang-Hyun Baek, Suwon-si (KR); Yuna Lee, Suwon-si (KR); Jinkwan Lee, Suwon-si (KR); Je-Woo Han, Suwon-si (KR); Jihye Lee, Suwon-si (KR); Seung Hee Han, Suwon-si (KR)

(21) Appl. No.: 19/218,956

(22) Filed: May 27, 2025

(30) Foreign Application Priority Data
Jun. 14, 2024 (KR) 10-2024-0077351

(51) Int. Cl. H10B 12/00

(52) U.S. Cl. CPC H10B 12/488; H10B 12/315; H10B 12/482

(57) ABSTRACT

A three-dimensional (3D) semiconductor device may include a semiconductor pattern that is on a substrate and extends in a first direction including a first edge portion, a second edge portion, and a channel region between the first edge portion and the second edge portion, a word line that extends around the channel region and extends in a second direction, and a bit line that is on a first side surface of the first edge portion of the semiconductor pattern and extends in a third direction. The first edge portion includes a first end adjacent to the first side surface, and a first thickness of the first end in the third direction is greater than a first center thickness of a center portion of the first edge portion in the third direction.

### CROSS-REFERENCE TO RELATED APPLICATION

This U.S. non-provisional patent application claims priority under 35 U.S.C. § 119 to Korean Patent Application No. 10-2024-0077351, filed on Jun. 14, 2024, in the Korean Intellectual Property Office, the entire contents of which are hereby incorporated by reference.

### TECHNICAL FIELD

The present disclosure relates to a three-dimensional semiconductor device and a method of fabricating the same, and in particular, to a highly reliable, highly integrated three-dimensional semiconductor device.

### BACKGROUND

Due to their small-sized, multifunctional, and/or low-cost characteristics, semiconductor devices are being esteemed as important elements in the electronics industry. The semiconductor devices are classified into a semiconductor memory device for storing data, a semiconductor logic device for processing data, and a hybrid semiconductor device including both memory and logic elements.

With the recent trend of high speed and low power consumption of electronic devices, semiconductor devices in the electronic devices are also desired to have high operating speeds and/or low operating voltages, and in order to satisfy this requirement, it is desirable to increase an integration density of the semiconductor device. However, as the integration density of the semiconductor device increases, the semiconductor device may suffer from deteriorated electrical characteristics and low production yield. Accordingly, many studies are being conducted to improve the electrical characteristics and production yield of the semiconductor device.

### SUMMARY

An embodiment of the present disclosure provides a three-dimensional semiconductor device with improved electrical and reliability characteristics.

According to an embodiment of the present disclosure, a three-dimensional (3D) semiconductor device may include a semiconductor pattern that is on a substrate and extends in a first direction parallel to a bottom surface of the substrate, the semiconductor pattern including a first edge portion, a second edge portion, and a channel region between the first edge portion and the second edge portion, a word line that extends around the channel region and extends in a second direction that is parallel to the bottom surface of the substrate and is orthogonal to the first direction, and a bit line that is on a first side surface of the first edge portion of the semiconductor pattern and extends in a third direction perpendicular to the bottom surface of the substrate, where the first edge portion includes a first end adjacent to the first side surface, and where a first thickness of the first end in the third direction is greater than a first center thickness of a center portion of the first edge portion in the third direction.

According to an embodiment of the present disclosure, a three-dimensional (3D) semiconductor device may include a semiconductor pattern that is on a substrate and extends in a first direction parallel to a bottom surface of the substrate, the semiconductor pattern including a first edge portion, a second edge portion, and a channel region between the first edge portion and the second edge portion, a word line that extends around the channel region and extends in a second direction that is parallel to the bottom surface of the substrate and is orthogonal to the first direction, and a bit line that is on a first side surface of the first edge portion of the semiconductor pattern and extends in a third direction perpendicular to the bottom surface of the substrate, where the first edge portion has a first recessed top surface that is recessed toward the substrate in the third direction.

According to an embodiment of the present disclosure, a three-dimensional (3D) semiconductor device may include a first stack and a second stack that are on a substrate and are spaced apart from each other in a first direction parallel to a bottom surface of the substrate, and a data storage pattern between the first stack and the second stack, where the first stack includes: a first semiconductor pattern that is on the substrate and extends in the first direction, the first semiconductor pattern including a first edge portion, a second edge portion, and a channel region between the first edge portion and the second edge portion, a first word line that extends around the channel region and extends in a second direction that is parallel to the bottom surface of the substrate and is orthogonal to the first direction, and a first bit line that is on a first side surface of the first edge portion of the first semiconductor pattern and extends in a third direction perpendicular to the bottom surface of the substrate. The first edge portion has a first end adjacent to the first side surface, and a first thickness of the first end in the third direction is greater than a first center thickness of a center portion of the first edge portion in the third direction.

### BRIEF DESCRIPTION OF THE DRAWINGS

FIG. 1 is a schematic circuit diagram illustrating a three-dimensional semiconductor device according to an embodiment of the present disclosure.

FIGS. 2A, 2B, and 2C are schematic perspective views illustrating a three-dimensional semiconductor device according to an embodiment of the present disclosure.

FIG. 3 is a plan view of a three-dimensional semiconductor device according to an embodiment of the present disclosure.

FIG. 4 is a perspective view illustrating semiconductor patterns, word lines, bit lines, and a data storage pattern of a three-dimensional semiconductor device according to an embodiment of the present disclosure.

FIG. 5A is a sectional view illustrating a three-dimensional semiconductor device according to an embodiment of the present disclosure, taken along a line A-A′ of FIG. 3.

FIG. 5B is a sectional view illustrating a three-dimensional semiconductor device according to an embodiment of the present disclosure, taken along a line B-B′ of FIG. 3.

FIGS. 6A, 6B, 6C, and 6D are enlarged views corresponding to a portion P1 of FIG. 5A.

FIGS. 7, 8, 9A, 9B, 10, 11, 12, 13, 14, 15, 16, 17A, 17B, 18, 19A, 19B, 20, 21A, 21B, 22A, 22B, 23, 24A, 24B, 25, 26A, 26B, 27, 28A, 28B, 29, 30A, and 30B are diagrams illustrating a method of fabricating a three-dimensional semiconductor device, according to an embodiment of the present disclosure.

FIG. 31 is a sectional view illustrating a three-dimensional semiconductor device according to an embodiment of the present disclosure, taken along the line A-A′ of FIG. 3.

FIGS. 32A, 32B, 32C, and 32D are enlarged views corresponding to a portion ‘P4’ of FIG. 31.

### DETAILED DESCRIPTION

To clarify the present disclosure, the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. The term “exposed” may be used to define a relationship between particular layers or surfaces, but it does not require the layer or surface to be free of other elements or layers thereon in the completed device. Components or layers described with reference to “overlap” in a particular direction may be at least partially obstructed by one another when viewed along a line extending in the particular direction or in a plane perpendicular to the particular direction.

Example embodiments of the present disclosure will now be described more fully with reference to the accompanying drawings, in which example embodiments are shown.

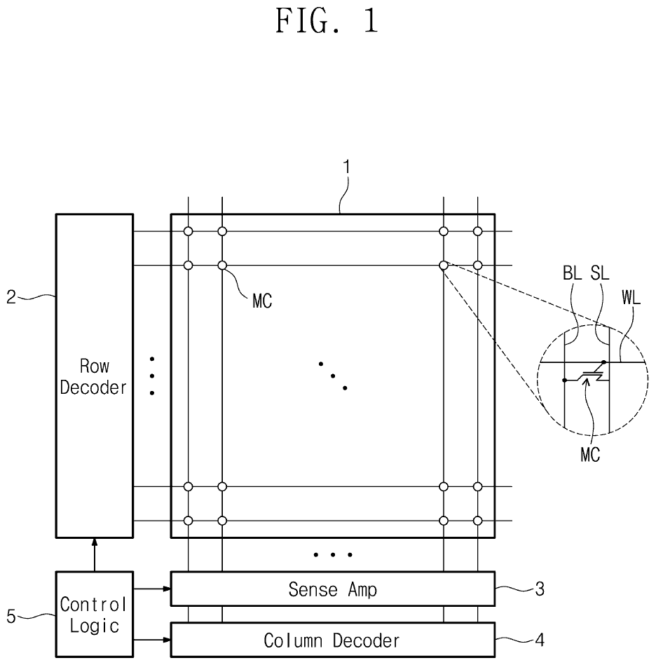

FIG. 1 is a schematic circuit diagram illustrating a three-dimensional semiconductor device according to an embodiment of the present disclosure.

Referring to FIG. 1, a three-dimensional semiconductor device may include a memory cell array 1, a row decoder 2, a sense amplifier 3, a column decoder 4, and a control logic 5.

The memory cell array 1 may include word lines WL, bit lines BL, source lines SL, and memory cells MC. The memory cells MC may be three-dimensionally arranged, and each of the memory cells MC may be connected to one of the word lines WL, one of the bit lines BL, and one of the source lines SL. In an embodiment, each of the memory cells MC may include one transistor including a memory layer or a data storing layer.

The row decoder 2 may be configured to decode address information, which is input from the outside, and to select one of the word lines WL of the memory cell array 1, based on the decoded address information. The address information decoded by the row decoder 2 may be provided to a row driver (not shown), and in this case, the row driver may provide respective voltages to the selected one of the word lines WL and the unselected ones of the word lines WL, in response to the control of a control circuit.

The sense amplifier 3 may be configured to sense, amplify, and output a difference in voltage between one of the bit lines BL, which is selected based on address information decoded by the column decoder 4, and a reference bit line.

The column decoder 4 may establish a data transmission path between the sense amplifier 3 and an external device (e.g., a memory controller). The column decoder 4 may be configured to decode address information, which is input from the outside, and to select one of the bit lines BL, based on the decoded address information.

The control logic 5 may be configured to generate control signals, which are used to control data-writing or data-reading operations on the memory cell array 1.

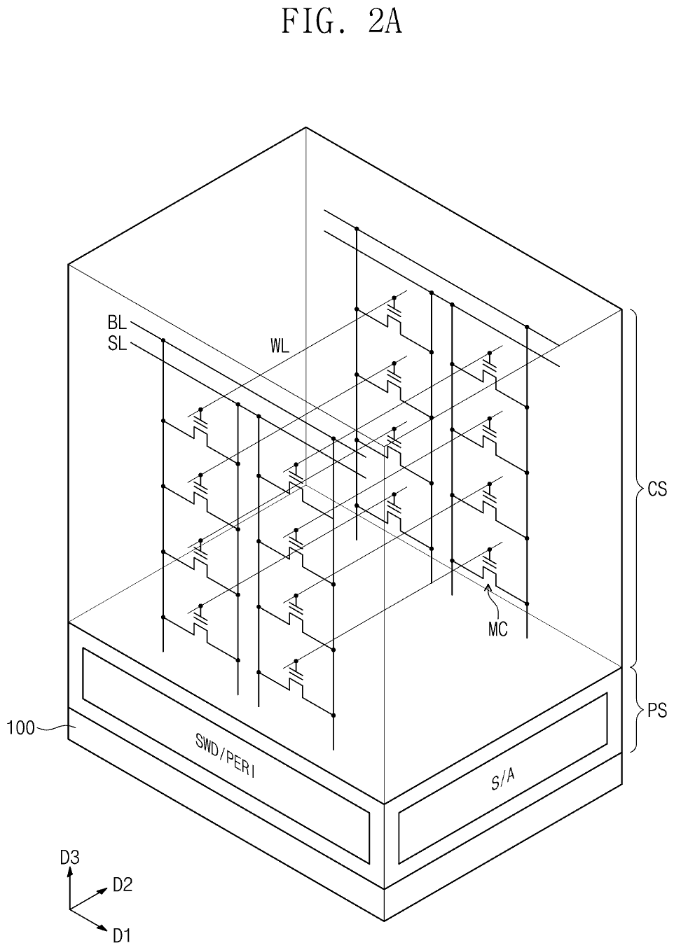

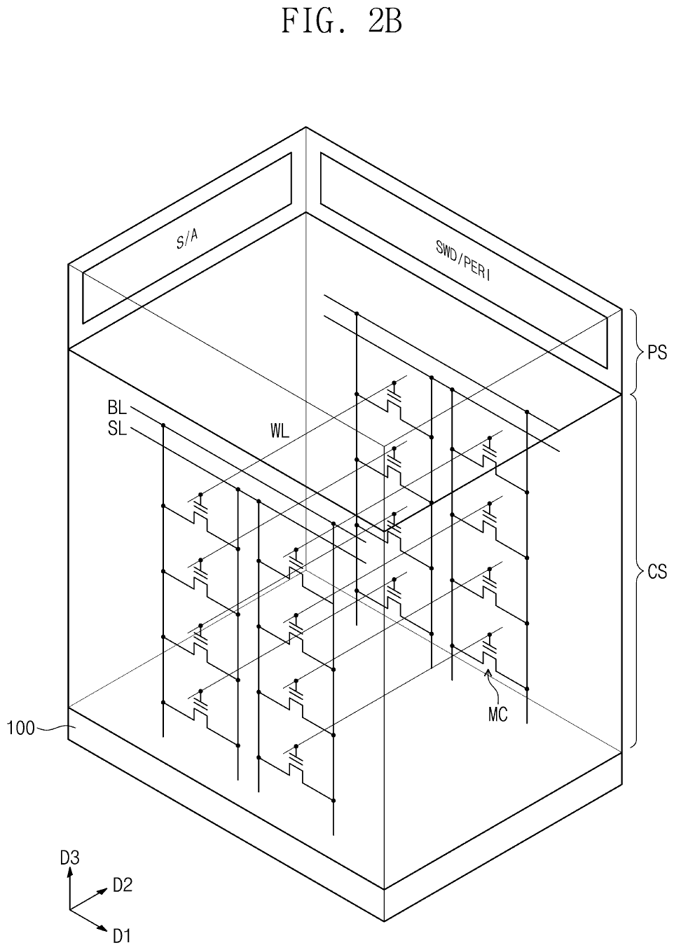

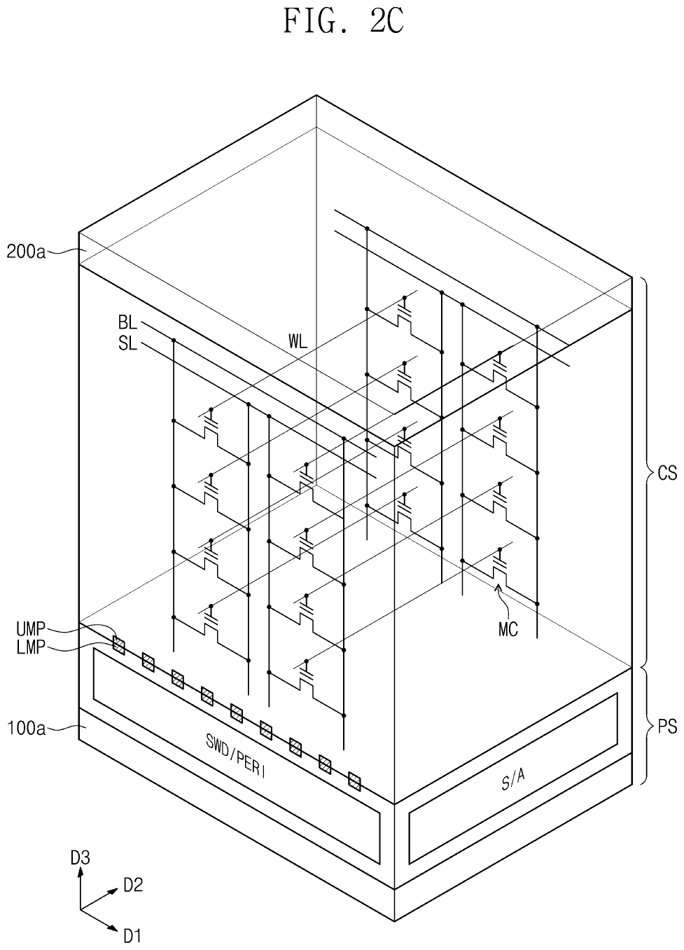

FIGS. 2A, 2B, and 2C are schematic perspective views illustrating a three-dimensional semiconductor device according to an embodiment of the present disclosure.

Referring to FIG. 2A, a three-dimensional semiconductor device may include a substrate 100, a peripheral circuit structure PS on the substrate 100, and a cell array structure CS on the peripheral circuit structure PS.

The peripheral circuit structure PS may include core and peripheral circuits formed on the substrate 100. The core and peripheral circuits may include the row and column decoders 2 and 4, the sense amplifier 3, and the control logic 5 described with reference to FIG. 1.

The substrate 100 may be a plate-shaped structure that extends parallel to a plane defined by a first direction D1 and a second direction D2. The first direction D1 and the second direction D2 may be parallel to a bottom surface of the substrate 100 and may not be parallel to each other. As an example, the first and second directions D1 and D2 may be horizontal directions that are orthogonal to each other. The peripheral circuit structure PS and the cell array structure CS may be sequentially stacked on the substrate 100 in a vertical direction D3 perpendicular to the bottom surface of the substrate 100.

The cell array structure CS may include the bit lines BL, the source lines SL, the word lines WL, and the memory cells MC therebetween. Each of the memory cells MC may be connected to one word line WL, one bit line BL, and one source line SL.

Referring to FIG. 2B, the semiconductor device may include the cell array structure CS on the substrate 100 and the peripheral circuit structure PS on the cell array structure CS. The cell array structure CS may be disposed between the substrate 100 and the peripheral circuit structure PS. The peripheral circuit structure PS may include the core and peripheral circuits.

Referring to FIG. 2C, the semiconductor device may have a chip-to-chip (C2C) structure. The peripheral circuit structure PS may include a first substrate 100a. Lower metal pads LMP may be provided in the uppermost portion of the peripheral circuit structure PS. The lower metal pads LMP may be electrically connected to the core and peripheral circuits. The lower metal pads LMP may be bonded to upper metal pads UMP of the cell array structure CS.

The cell array structure CS may include a second substrate 200a, and the upper metal pads UMP may be provided in the lowermost portion of the cell array structure CS. The upper metal pads UMP may be electrically connected to the bit lines BL, the source lines SL, and the word lines WL. The upper metal pads UMP may be electrically connected to the memory cells MC.

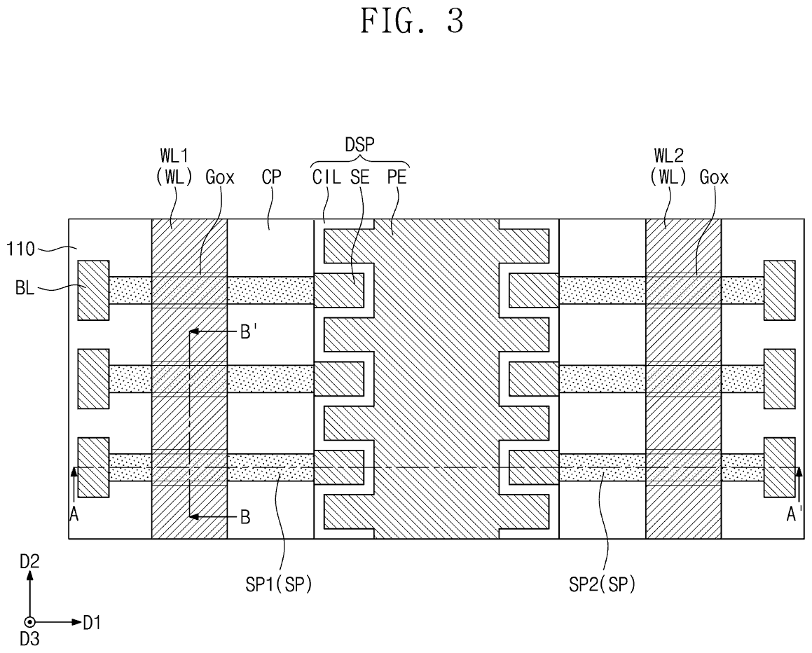

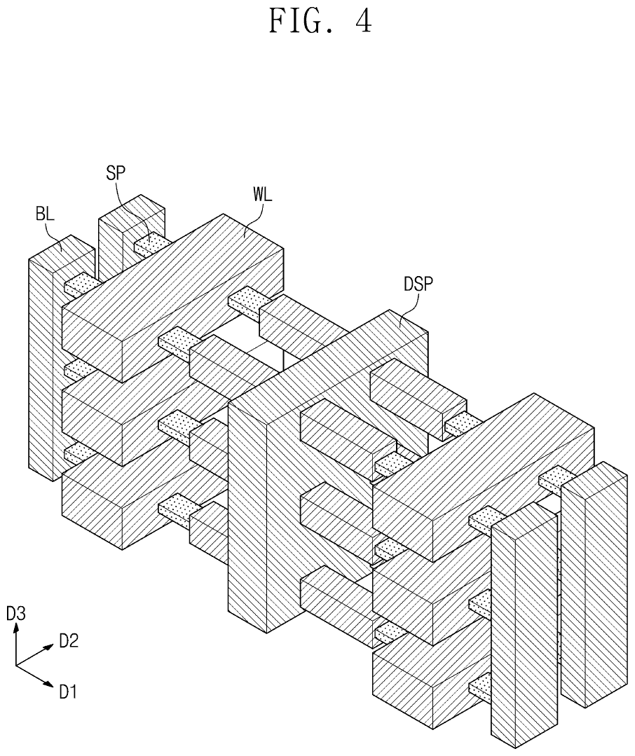

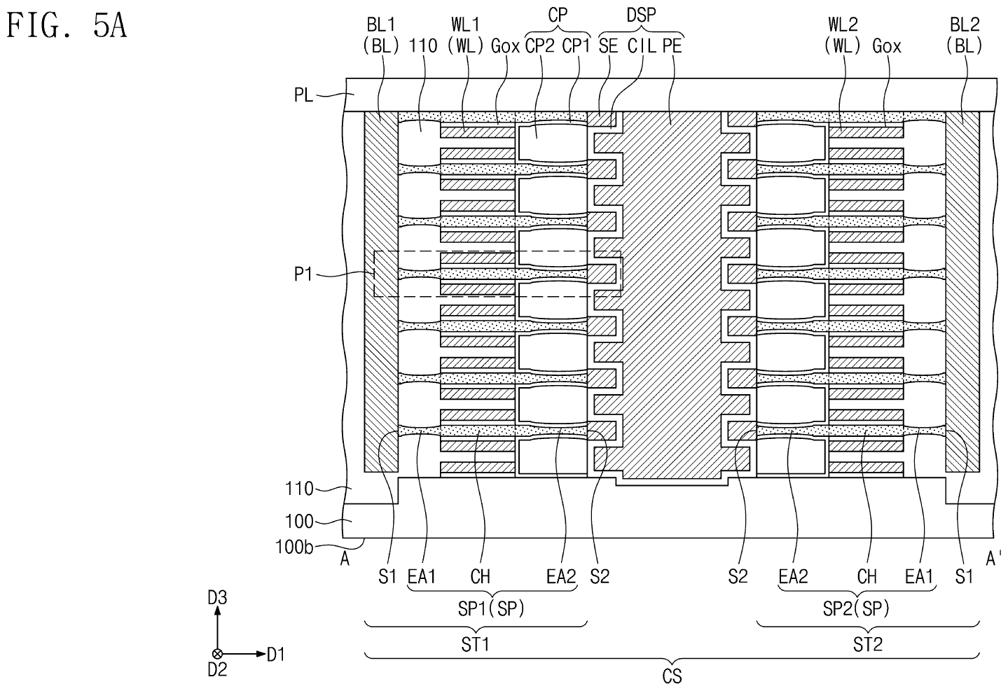

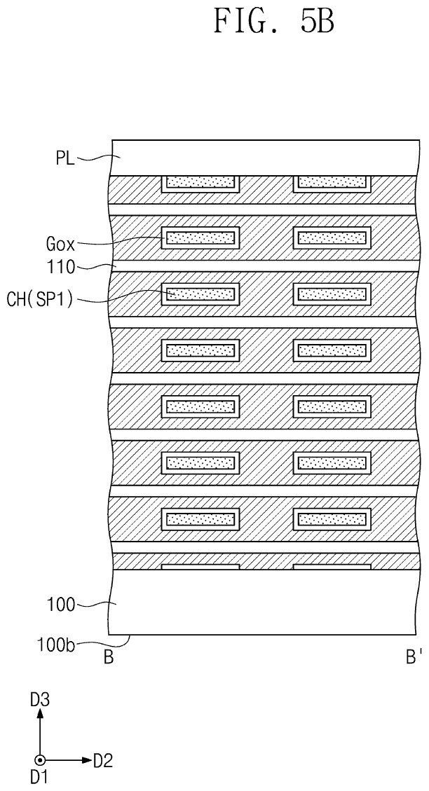

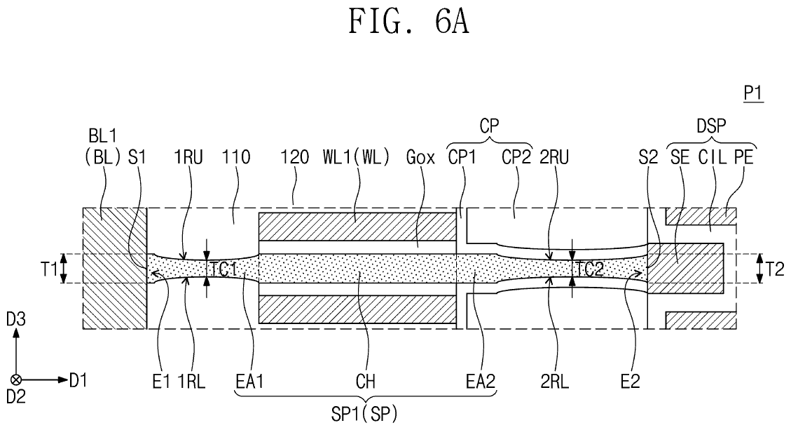

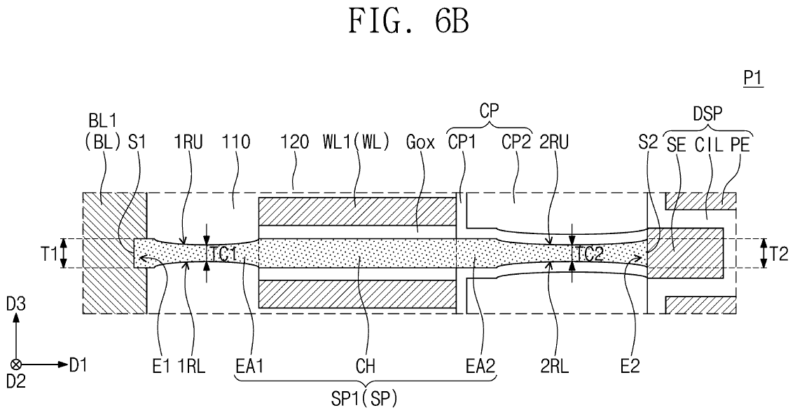

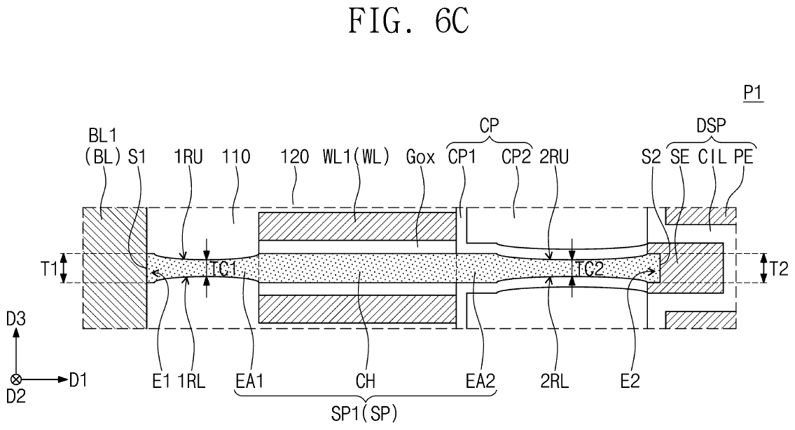

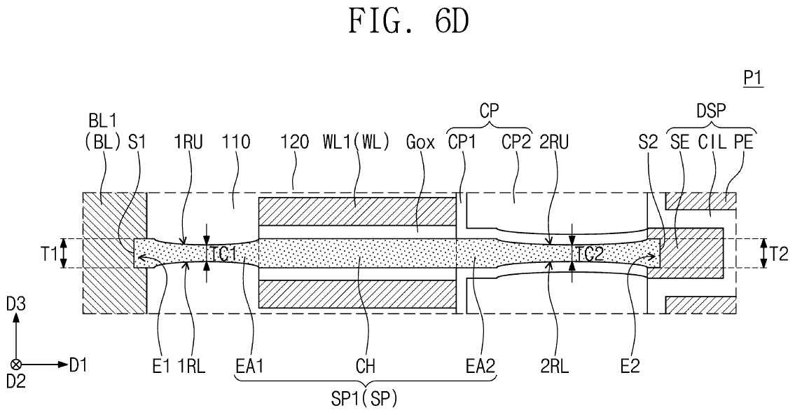

FIG. 3 is a plan view of a three-dimensional semiconductor device according to an embodiment of the present disclosure. FIG. 4 is a perspective view illustrating semiconductor patterns, word lines, bit lines, and a data storage pattern of a three-dimensional semiconductor device according to an embodiment of the present disclosure. FIG. 5A is a sectional view corresponding to a line A-A′ of FIG. 3. FIG. 5B is a sectional view corresponding to a line B-B′ of FIG. 3. FIGS. 6A to 6D are enlarged sectional views corresponding to a portion P1 of FIG. 5A, according to some embodiments of the present disclosure.

Referring to FIGS. 3 to 5B, the three-dimensional semiconductor device may include the substrate 100. In an embodiment, the substrate 100 may be a semiconductor substrate, an insulating substrate, a silicon-on-insulator (SOI) substrate, or a germanium-on-insulator (GOI) substrate. The semiconductor substrate may be, for example, a silicon substrate, a germanium substrate, or a silicon-germanium substrate. The substrate 100 may be a plate-shaped structure that extends parallel to a plane defined by the first direction D1 and the second direction D2. In the present specification, the first direction D1 and the second direction D2 may be parallel to a bottom surface 100b of the substrate 100 and may not be parallel to each other. The third direction D3 may be the vertical direction D3 perpendicular to the bottom surface of the substrate 100. In an embodiment, the first to third directions D1, D2, and D3 may be orthogonal to each other.

The cell array structure CS may be provided on the substrate 100. The cell array structure CS may include a first stack ST1 and a second stack ST2, which are spaced apart from each other in the first direction D1, and a data storage pattern DSP therebetween. In an embodiment, although not shown, the cell array structure CS may include a plurality of cell array structures CS, which are spaced apart from each other in the first direction D1. Hereinafter, just one cell array structure CS will be described, for brevity's sake, but the others of the cell array structures CS may also have substantially the same features as described below.

Each of the first and second stacks ST1 and ST2 may include semiconductor patterns SP, the word lines WL, the bit lines BL, first capping patterns CP1, second capping patterns CP2, and a gapfill insulating pattern 110. In an embodiment, the first and second stacks ST1 and ST2 may be provided to have a mirror symmetry with respect to the data storage pattern DSP.

The semiconductor pattern SP may extend in the first direction D1, on the substrate 100. The semiconductor pattern SP may be spaced apart from the substrate 100. That is, the semiconductor pattern SP may be floated from the substrate 100. In an embodiment, a plurality of semiconductor patterns SP may be provided. The semiconductor patterns SP may be spaced apart from each other in the second direction D2 and the vertical direction D3. The semiconductor patterns SP, which are spaced apart from each other in the vertical direction D3, may be vertically overlapped with each other, when viewed in a plan view. Side surfaces of the semiconductor patterns SP, which are spaced apart from each other in the vertical direction D3, may be aligned with each other in the vertical direction D3.

The semiconductor pattern SP may include a first edge portion EA1 and a second edge portion EA2, which are spaced apart from each other in the first direction D1, and a channel region CH therebetween. The channel region CH of the semiconductor pattern SP may be enclosed or at least partially surrounded by the word line WL. The first edge portion EA1 of the semiconductor pattern SP may be adjacent to the bit line BL to be described below. The first edge portion EA1 may be electrically connected to the bit line BL. The second edge portion EA2 may be adjacent to the data storage pattern DSP to be described below. The second edge portion EA2 may be electrically connected to the data storage pattern DSP.

The semiconductor pattern SP may have a first side surface S1 and a second side surface S2, which are opposite to each other in the first direction D1. The first side surface S1 may be a side surface of the first edge portion EA1, and the second side surface S2 may be a side surface of the second edge portion EA2. The first side surface S1 of the semiconductor pattern SP may be adjacent to the bit line BL, and the second side surface S2 may be adjacent to the data storage pattern DSP.

The semiconductor pattern SP may be formed of or include at least one of single-crystalline semiconductor materials, polycrystalline semiconductor materials, oxide semiconductor materials, and two-dimensional materials. In an embodiment, the single-crystalline semiconductor material may be single-crystalline silicon. In an embodiment, the polycrystalline semiconductor materials may be poly silicon. In an embodiment, the oxide semiconductor materials may be indium gallium zinc oxide (IGZO). In an embodiment, the two-dimensional material may be MoS₂, WS₂, MoSe₂, or WSe₂.

In an embodiment, each of the first and second edge portions EA1 and EA2 of the semiconductor pattern SP may include an impurity region that is doped with impurities (e.g., n-type or p-type impurities). The impurity region may be used as a source/drain region of a transistor.

The semiconductor pattern SP may include a first semiconductor pattern SP1 provided in the first stack ST1 and a second semiconductor pattern SP2 provided in the second stack ST2. The first semiconductor pattern SP1 may be spaced apart from the second semiconductor pattern SP2 in the first direction D1. The first edge portion EA1, the channel region CH, and the second edge portion EA2 of the first semiconductor pattern SP1 may be sequentially arranged in the first direction D1. The first edge portion EA1, the channel region CH, and the second edge portion EA2 of the second semiconductor pattern SP2 may be sequentially arranged in an opposite direction of the first direction D1.

The word line WL may extend in the second direction D2 and may enclose the channel region CH of the semiconductor pattern SP. In an embodiment, the word line WL may have a structure (i.e., a gate-all-around structure) fully surrounding the channel region CH of the semiconductor pattern SP. Each word line WL may be provided to enclose the channel region CH of each of the semiconductor patterns SP, which are spaced apart from each other in the second direction D2. In an embodiment, a plurality of word lines WL may be provided. Each of the word lines WL may be provided to surround the channel region CH of a corresponding one of the semiconductor patterns SP, which are spaced apart from each other in the vertical direction D3, and may extend in the second direction D2. The word lines WL may be spaced apart from each other in the vertical direction D3.

The word line WL may include a first word line WL1, which is provided in the first stack ST1 to enclose the channel region CH of the first semiconductor pattern SP1, and a second word line WL2, which is provided in the second stack ST2 to enclose the channel region CH of the second semiconductor pattern SP2. The first word line WL1 and the second word line WL2 may be spaced apart from each other in the first direction D1.

The word line WL may be formed of or include at least one of doped polysilicon, metallic materials (e.g., Al, Cu, Ti, Ta, Ru, W, Mo, Pt, Ni, Co), conductive metal nitride materials (e.g., TiN, TaN, WN, NbN, TiAlN, TiSiN, TaSiN, RuTiN), conductive metal silicide materials, or conductive metal oxide materials (e.g., PtO, RuO₂, IrO₂, SrRuO₃ (SRO), (BaSr) RuO₃ (BSRO), CaRuO₃ (CRO), LSCo), but the present disclosure is not limited to this example. The word line WL may be provided to have a single-layered or multi-layered structure formed of the afore-described materials. In an embodiment, the word line WL may include a two-dimensional semiconductor material (e.g., graphene, carbon nanotube, or combinations thereof).

A gate insulating layer Gox may be interposed between the word line WL and the semiconductor pattern SP. The gate insulating layer Gox may enclose or extend around the semiconductor pattern SP. The word line WL may be provided to enclose the channel region CH of the semiconductor pattern SP, on the gate insulating layer Gox. In an embodiment, a plurality of gate insulating layers Gox may be provided. Each of the gate insulating layers Gox may enclose or extend around a corresponding one of the semiconductor patterns SP.

The gate insulating layer Gox may include at least one of silicon oxide, silicon oxynitride, or a high-k dielectric material. The high-k dielectric material may include a metal oxide material or a metal oxynitride material. For example, the high-k dielectric material, which is used as the gate insulating layer Gox, may include at least one of HfO₂, HfSiO, HfSiON, HfTaO, HfTiO, HfZrO, ZrO₂, or Al₂O₃, but the present disclosure is not limited to this example. The high-k dielectric material may be defined as a material having a dielectric constant higher than silicon oxide.

Hereinafter, some embodiments of the present disclosure will be described in more detail with reference to FIGS. 6A to 6D.

Referring to FIG. 6A, the first edge portion EA1 of the semiconductor pattern SP may have a first recessed top surface 1RU, which is recessed toward the substrate 100. The first recessed top surface 1RU may be located at a height lower (or less) than the topmost surface of the first edge portion EA1. In the present specification, the height may mean a distance measured from the bottom surface 100b of the substrate 100 in the vertical direction D3. In addition, the first edge portion EA1 may have a first recessed bottom surface 1RL, which is recessed in a direction away from the substrate 100 (i.e., opposite to the vertical direction D3). The first recessed bottom surface 1RL may be located at a height higher (or greater) than the bottommost surface of the first edge portion EA1. The first recessed top surface 1RU and the first recessed bottom surface 1RL may be opposite to each other in the vertical direction D3.

The second edge portion EA2 of the semiconductor pattern SP may have a second recessed top surface 2RU, which is recessed toward the substrate 100. The second recessed top surface 2RU may be located at a height lower than the topmost surface of the second edge portion EA2. In addition, the second edge portion EA2 may have a second recessed bottom surface 2RL, which is recessed in a direction away from the substrate 100 (i.e., opposite to the vertical direction D3). The second recessed bottom surface 2RL may be located at a height higher than the bottommost surface of the second edge portion EA2. The second recessed top surface 2RU and the second recessed bottom surface 2RL may be opposite to each other in the vertical direction D3.

The first edge portion EA1 of the semiconductor pattern SP may include a first end E1 adjacent to the first side surface S1. That is, the first side surface S1 may be a side surface of the semiconductor pattern SP and may be a side surface of the first end E1 of the first edge portion EA1. The first edge portion EA1 may have a first thickness T1 at the first end E1. The first thickness T1 may be the largest thickness of the first end E1. In the present specification, the thickness may be a length measured in the vertical direction D3. The first edge portion EA1 may have a first center thickness TC1 at its center portion. The first thickness T1 may be larger than the first center thickness TC1. In an embodiment, the first center thickness TC1 may mean a thickness between the first recessed bottom surface 1RL and the first recessed top surface 1RU of the first edge portion EA1.

The second edge portion EA2 of the semiconductor pattern SP may include a second end E2 adjacent to the second side surface S2. In other words, the second side surface S2 may be an opposite side surface of the semiconductor pattern SP and may be a side surface of the second end E2 of the second edge portion EA2. The second edge portion EA2 may have a second thickness T2 at the second end E2. The second thickness T2 may be the largest thickness of the second end E2. The second edge portion EA2 may have a second center thickness TC2 at its center portion. The second thickness T2 may be larger than the second center thickness TC2. In an embodiment, the second center thickness TC2 may mean a thickness between the second recessed bottom surface 2RL and the second recessed top surface 2RU of the second edge portion EA2.

The first side surface S1 may be in contact with a side surface of the bit line BL. Accordingly, the bit line BL and the semiconductor pattern SP may be electrically connected to each other. The first side surface S1 may be aligned with the side surface of the bit line BL in the vertical direction D3. The first end E1 of the first edge portion EA1 of the semiconductor pattern SP may be disposed in a gapfill insulating pattern 110, which will be described below. That is, the first edge portion EA1 may not extend into the bit line BL.

The second side surface S2 may be in contact with a side surface of the data storage pattern DSP. Accordingly, the semiconductor pattern SP and the data storage pattern DSP may be electrically connected to each other. The second side surface S2 may be aligned with a side surface of a storage electrode SE of the data storage pattern DSP, which will be described below, in the vertical direction D3. The second end E2 of the second edge portion EA2 of the semiconductor pattern SP may be placed in or extend into a capping pattern CP, which will be described below. In other words, the second edge portion EA2 may not extend into the data storage pattern DSP.

Referring to FIG. 6B, the first edge portion EA1 of the semiconductor pattern SP may extend into the bit line BL. The first end E1 of the first edge portion EA1 may extend into the bit line BL. That is, the first side surface S1 may be placed in or extend into the bit line BL. The first end E1 of the first edge portion EA1 may be placed in or extend into the bit line BL. Accordingly, the bit line BL and the semiconductor pattern SP may be electrically connected to each other.

Referring to FIG. 6C, the second edge portion EA2 of the semiconductor pattern SP may extend into the data storage pattern DSP. The second edge portion EA2 of the semiconductor pattern SP may extend into the storage electrode SE to be described below. The second end E2 of the second edge portion EA2 may extend into the data storage pattern DSP. The second end E2 of the second edge portion EA2 may extend into the storage electrode SE. That is, the second side surface S2 may be placed in or extend into the data storage pattern DSP. In detail, the second side surface S2 may be placed in or extend into the storage electrode SE. The second end E2 of the second edge portion EA2 may be placed in or extend into the storage electrode SE. Accordingly, the semiconductor pattern SP and the data storage pattern DSP may be electrically connected to each other.

Referring to FIG. 6D, the first edge portion EA1 of the semiconductor pattern SP may extend into the bit line BL, and the second edge portion EA2 may extend into the data storage pattern DSP. The first end E1 of the first edge portion EA1 may extend into the bit line BL, and the second end E2 of the second edge portion EA2 may extend into the data storage pattern DSP. The second end E2 of the second edge portion EA2 may extend into the storage electrode SE. That is, the first side surface S1 may be placed in or extend into the bit line BL, and the second side surface S2 may be placed in or extend into the data storage pattern DSP (e.g., the storage electrode SE). The first end E1 of the first edge portion EA1 may be placed in or extend into the bit line BL. The second end E2 of the second edge portion EA2 may be placed in or extend into the data storage pattern DSP (e.g., the storage electrode SE).

Referring back to FIGS. 3 to 5B, the bit line BL may be provided on the first side surface S1 of the semiconductor pattern SP. The bit line BL on the first side surface S1 of the semiconductor pattern SP may extend in the vertical direction D3. Thus, each bit line BL may be in contact with the first side surface S1 of each of the semiconductor patterns SP, which are spaced apart from each other in the vertical direction D3, and may be electrically connected to the semiconductor patterns SP. However, as described with reference to FIGS. 6B and 6D, the first side surface S1 may be disposed in the bit line BL. In an embodiment, a plurality of bit lines BL may be provided. The bit lines BL may be spaced apart from each other in the second direction D2.

The bit line BL may be formed of or include at least one of, for example, doped polysilicon, metallic materials (e.g., Al, Cu, Ti, Ta, Ru, W, Mo, Pt, Ni, Co), conductive metal nitride materials (e.g., TiN, TaN, WN, NbN, TiAlN, TiSiN, TaSiN, RuTiN), conductive metal silicide materials, or conductive metal oxide materials (e.g., PtO, RuO₂, IrO₂, SrRuO₃ (SRO), (BaSr) RuO₃ (BSRO), CaRuO₃ (CRO), LSCo), but the present disclosure is not limited to this example. The bit line BL may be provided to have a single-layered or multi-layered structure formed of the above-described materials. In an embodiment, the bit line BL may be formed of or include at least one of two-dimensional semiconductor materials (e.g., graphene, carbon nanotube, or combinations thereof).

The bit line BL may include a first bit line BL1, which is provided on the first side surface S1 of the first semiconductor pattern SP1, in the first stack ST1. In addition, the bit line BL may include a second bit line BL2, which is provided on the first side surface S1 of the second semiconductor pattern SP2, in the second stack ST2.

The data storage pattern DSP may be interposed between the first stack ST1 and the second stack ST2. The data storage pattern DSP may be interposed between the first semiconductor pattern SP1 and the second semiconductor pattern SP2. The data storage pattern DSP may be in contact with the second side surface S2 of the first semiconductor pattern SP1 and may be electrically connected to the first semiconductor pattern SP1. The data storage pattern DSP may be in contact with the second side surface S2 of the second semiconductor pattern SP2 and may be electrically connected to the second semiconductor pattern SP2. However, as described with reference to FIGS. 6C and 6D, the second side surface S2 may be placed in or extend into the data storage pattern DSP (e.g., the storage electrode SE).

The data storage pattern DSP may include the storage electrode SE, a plate electrode PE, and a capacitor dielectric layer CIL interposed therebetween. As an example, three-dimensional semiconductor device may be a dynamic random access memory (DRAM) device, and here, the data storage pattern DSP may be a capacitor. The storage electrode SE may be spaced apart from the plate electrode PE, with the capacitor dielectric layer CIL interposed therebetween.

Each of the storage and plate electrodes SE and PE may include a conductive material. In an embodiment, each of the storage and plate electrodes SE and PE may be formed of or include at least one of doped silicon (Si), doped silicon germanium (SiGe), metallic materials (e.g., Ti, Mo, W, Cu, Al, Ta, Ru, Ir, Co, Pt, Au, and Ag), metal nitride materials (e.g., nitride materials containing Ti, Mo, W, Cu, Al, Ta, Ru, Ir, Co, Pt, Au, and Ag, titanium silicon nitride (TiSiN), titanium aluminum nitride (TiAlN), and tantalum aluminum nitride (TaAlN)), conductive oxide materials (e.g., PtO, RuO₂, IrO₂, SrRuO₃ (SRO), (BaSr) RuO₃ (BSRO), CaRuO₃ (CRO), and LSCo), or metal silicide materials. Each of the storage and plate electrodes SE and PE may be a single layer, which is made of a single material, or a composite layer including two or more materials.

In an embodiment, the capacitor dielectric layer CIL may include at least one of metal oxide materials (e.g., HfO₂, ZrO₂, Al₂O₃, La₂O₃, Ta₂O₃, and TiO₂) and perovskite dielectric materials (e.g., SrTiO₃ (STO), (Ba,Sr)TiO₃ (BST), BaTiO₃, PZT, and PLZT).

In another embodiment, the data storage pattern DSP may be a variable resistance pattern whose resistance can be switched to one of at least two states by an electric pulse applied thereto. For example, the data storage pattern DSP may be formed of or include at least one of phase-change materials whose crystal state can be changed depending on an amount of a current applied thereto, perovskite compounds, transition metal oxides, magnetic materials, ferromagnetic materials, or antiferromagnetic materials.

The storage electrode SE may be provided on and extend from the second side surface S2 of the first semiconductor pattern SP1 in the first direction D1. The storage electrode SE may be provided on and extend from the second side surface S2 of the second semiconductor pattern SP2 in an opposite direction of the first direction D1. Although not shown, a silicide pattern (not shown) may be provided between the storage electrode SE and the first semiconductor pattern SP1 and between the storage electrode SE and the second semiconductor pattern SP2. The silicide pattern may be formed of or include at least one of metal silicide materials (e.g., containing Ti, Mo, W, Cu, Al, Ta, Ru, Ir, and Co). In an embodiment, a plurality of storage electrodes SE may be provided to be spaced apart from each other in the vertical direction D3.

The plate electrode PE may include a first region, which extends in the vertical direction D3, and a second region, which extends from the first region in the first direction D1 or the opposite direction thereof. The second region of the plate electrode PE may be interposed between the storage electrodes SE, which are spaced apart from each other in the vertical direction D3.

The gapfill insulating pattern 110 may be provided on the substrate 100. The gapfill insulating pattern 110 may cover or at least partially overlap a side surface of the cell array structure CS in the first direction D1. The gapfill insulating pattern 110 may be interposed between the bit line BL and the word line WL, between the semiconductor patterns SP, which are spaced apart from each other in the vertical direction D3, between the first edge portions EA1, which are spaced apart from each other in the second direction D2, and between the word lines WL, which are spaced apart from each other in the vertical direction D3. The gapfill insulating pattern 110 may cover or at least partially overlap the first edge portion EA1 in the vertical direction D3. The gapfill insulating pattern 110 may include a single or composite layer including an insulating material.

The capping pattern CP may be provided in the cell array structure CS. The capping pattern CP may be interposed between the word lines WL and the data storage pattern DSP. The capping pattern CP may cover or at least partially overlap the second edge portion EA2 in the vertical direction D3. The capping pattern CP may be interposed between the second edge portions EA2 of the semiconductor patterns SP, which are spaced apart from each other in the vertical direction D3. The capping pattern CP may be interposed between the second edge portions EA2 of the semiconductor patterns SP, which are spaced apart from each other in the second direction D2.

The capping pattern CP may include the first capping pattern CP1 enclosing or extending around the second edge portion EA2 of the semiconductor pattern SP and the second capping pattern CP2 on the first capping pattern CP1. The first capping pattern CP1 may conformally cover or at least partially overlap the second edge portion EA2 of the semiconductor pattern SP, a side surface of the gapfill insulating pattern 110, a side surface of the word line WL, and a side surface of the gate insulating layer Gox. Each of the first and second capping patterns CP1 and CP2 may include an insulating material. The second capping pattern CP2 may include a single layer or a composite layer.

A protection layer PL may be provided on the cell array structure CS. The protection layer PL may cover or at least partially overlap the top surfaces of the first stack ST1, the second stack ST2, and the data storage pattern DSP in the vertical direction D3. The protection layer PL may include a single or composite layer including an insulating material. The protection layer PL may include a plurality of upper interconnection lines (not shown) provided therein. At least one of the upper interconnection lines may be electrically connected to the bit line BL, and others may be electrically connected to the data storage pattern DSP. In addition, although not shown, word line pads (not shown) may be provided on the side surface of the cell array structure CS and may be electrically connected to the word lines WL.

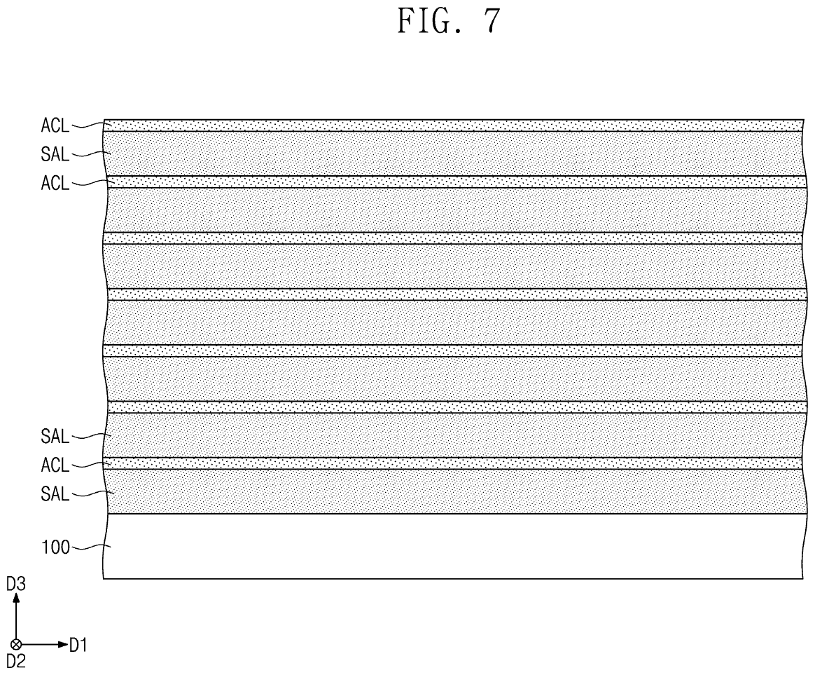

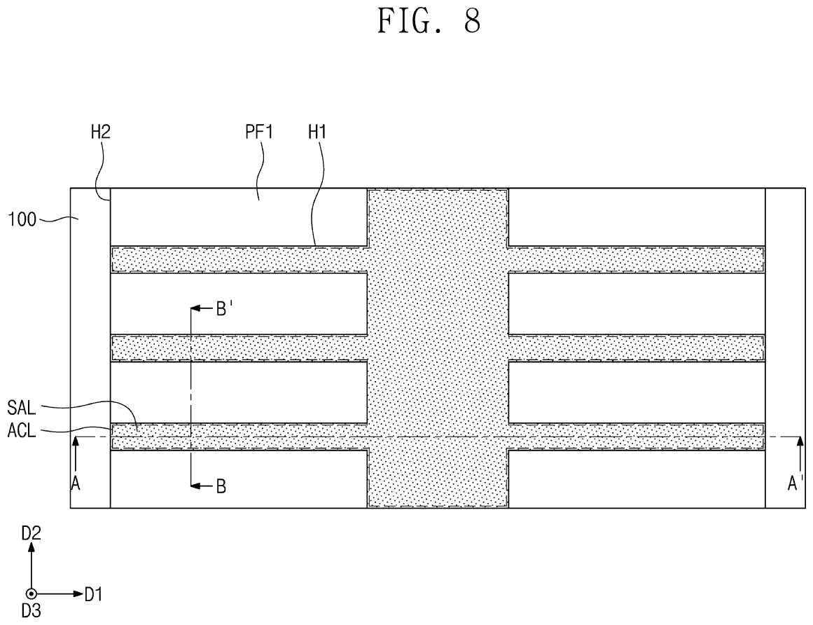

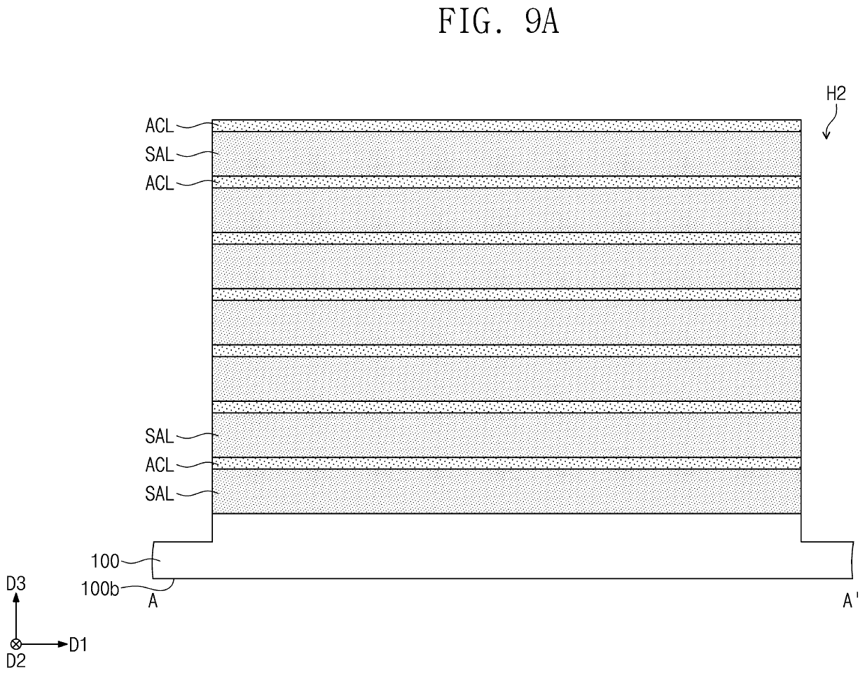

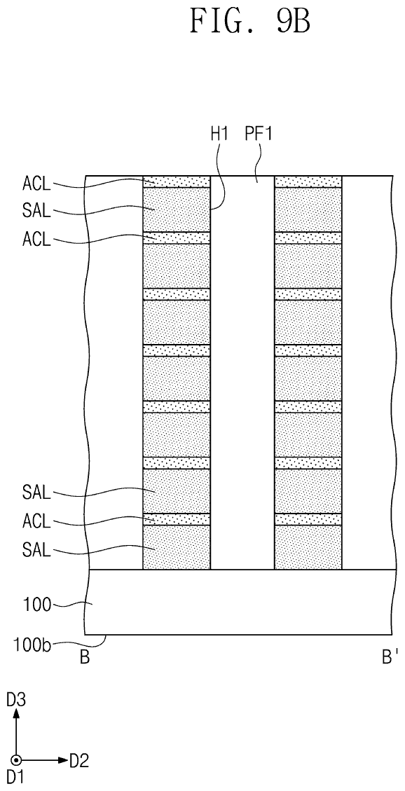

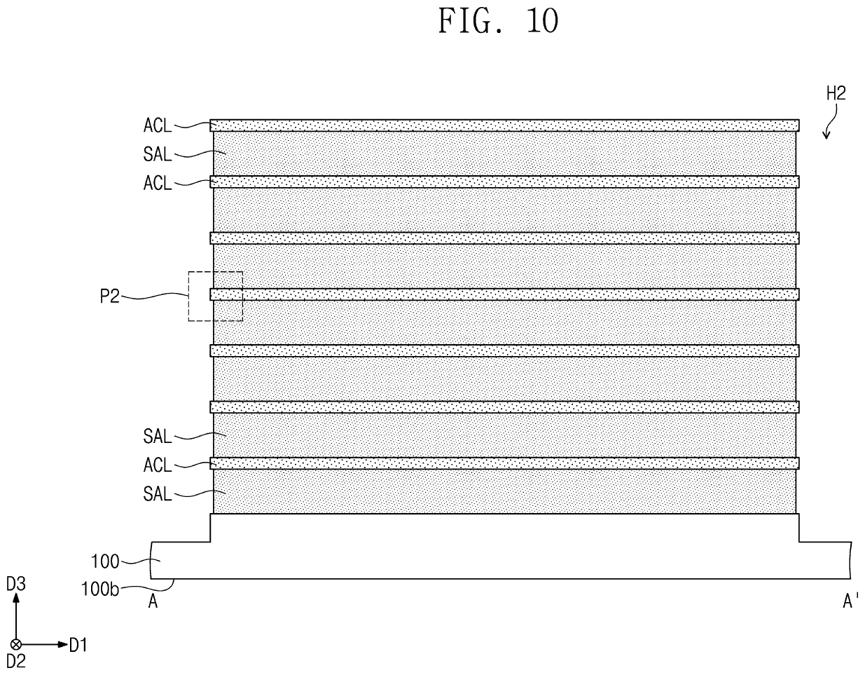

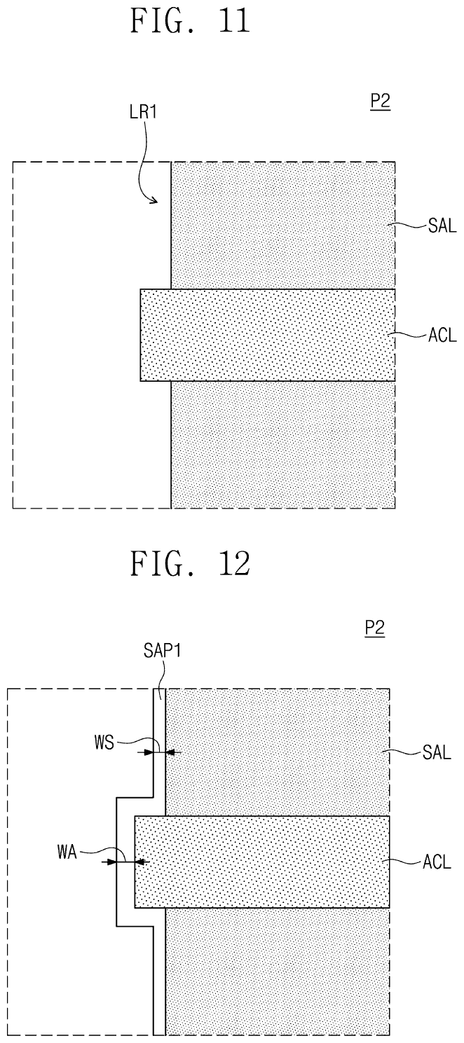

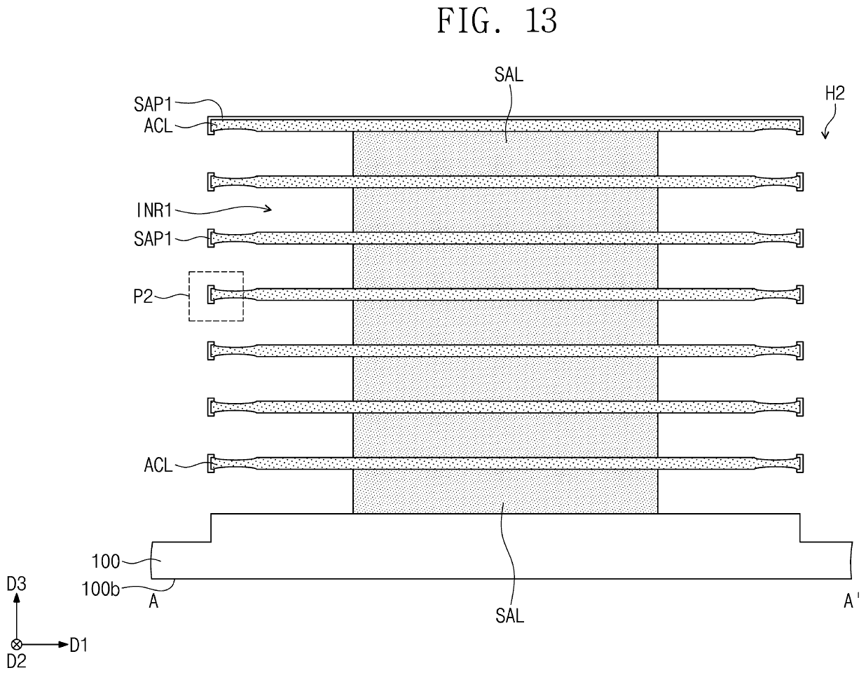

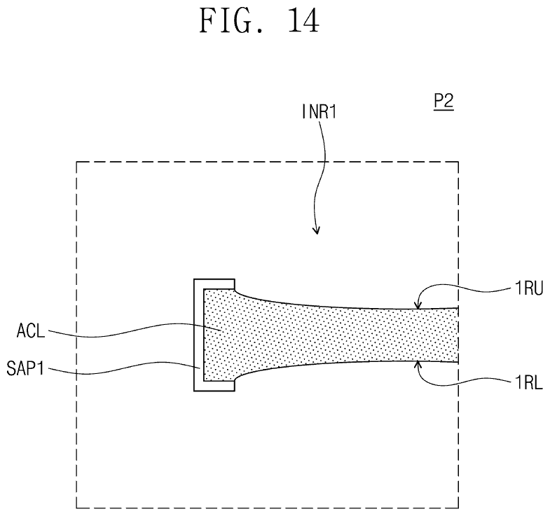

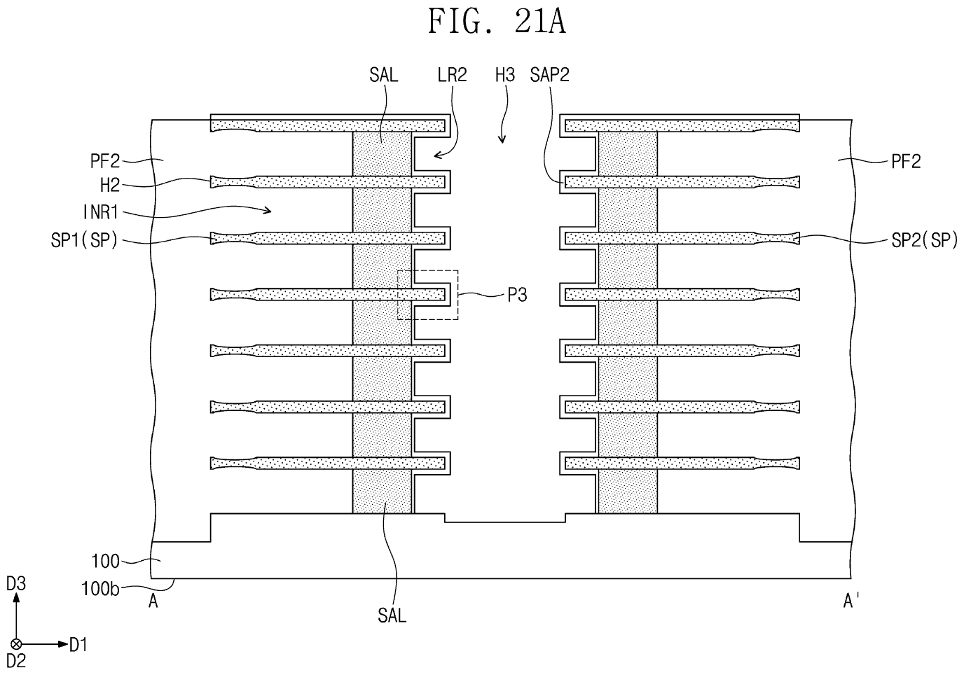

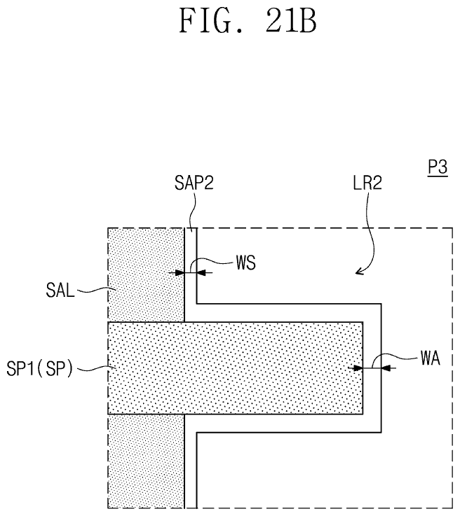

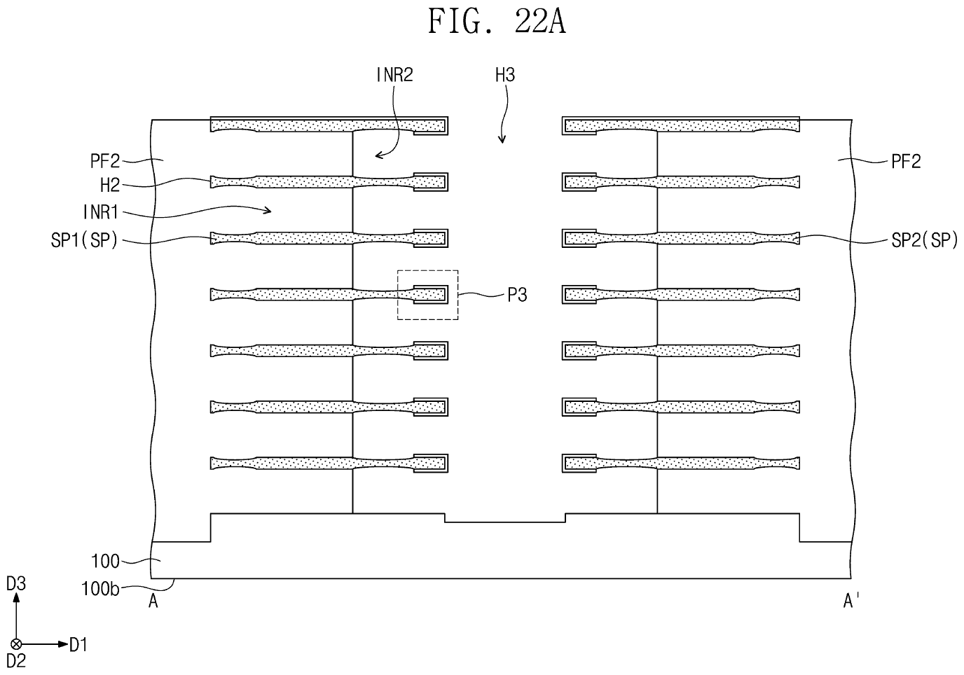

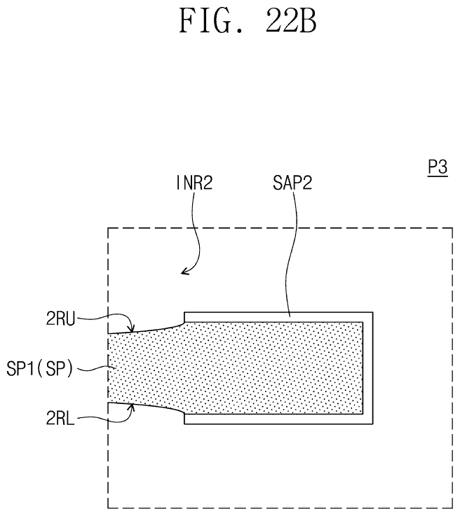

FIGS. 7 to 30B are diagrams illustrating a method of fabricating a three-dimensional semiconductor device, according to an embodiment of the present disclosure. In detail, FIGS. 7, 9A, 10, 13, 15, 17A, 19A, 20, 21A, 22A, 24A, 26A, 28A, and 30A are sectional views corresponding to the line A-A′ of FIG. 3. FIGS. 8, 16, 18, 23, 25, 27, and 29 are plan views illustrating a fabrication method according to an embodiment of the present disclosure. FIGS. 9B, 17B, 19B, 24B, 26B, 28B, and 30B are sectional views corresponding to the line B-B′ of FIG. 3. FIGS. 11 and 12 are enlarged views illustrating a portion ‘P2’ of FIG. 10. FIG. 14 is an enlarged view illustrating a portion ‘P2’ of FIG. 13. FIG. 21B is an enlarged view illustrating a portion ‘P3’ of FIG. 21A. FIG. 22B is an enlarged view illustrating a portion ‘P3’ of FIG. 22A. Hereinafter, a method of fabricating a three-dimensional semiconductor device, according to an embodiment of the present disclosure, will be described in more detail with reference to FIGS. 7 to 30B. For concise description, a previously described element may be identified by the same reference number without repeating an overlapping description thereof.

Referring to FIG. 7, sacrificial layers SAL and active layers ACL may be alternately stacked on the substrate 100. Each of the sacrificial and active layers SAL and ACL may include a semiconductor material. The sacrificial layers SAL may include a material having an etch selectivity with respect to the active layers ACL. Thus, the active layers ACL may be hardly or less removed when the sacrificial layers SAL are removed in a subsequent step. In an embodiment, the active and sacrificial layers ACL and SAL may be formed of or include at least one of silicon (Si), germanium (Ge), or silicon germanium (SiGe), but the material of the sacrificial layers SAL may be different from that of the active layers ACL. In an embodiment, the active layers ACL may include silicon (Si), and the sacrificial layers SAL may include silicon-germanium (SiGe). A thickness of the sacrificial layers SAL may be larger than a thickness of the active layers ACL.

Referring to FIGS. 8 and 9A to 9B, a portion of each of the sacrificial and active layers SAL and ACL may be removed to form first holes H1 on the substrate 100. The first holes H1 may extend in the first direction D1 and may be spaced apart from each other in the first and second directions D1 and D2. Portions of a top surface of the substrate 100 may be exposed to the outside through the first holes H1. As a result of the removal process, the sacrificial and active layers SAL and ACL may be formed to include regions, which are elongated in the first direction D1 between the first holes H1 spaced apart from each other in the second direction D2, and regions, which are elongated in the second direction D2 between the first holes H1 spaced apart from each other in the first direction D1.

First preliminary filling patterns PF1 may be formed to cover or overlap the exposed portions of the top surface of the substrate 100 in the vertical direction D3 and to at least partially fill the first holes H1. In an embodiment, the first preliminary filling pattern PF1 may include an insulating material. The first preliminary filling patterns PF1 may be spaced apart from each other in the first and second directions D1 and D2.

Portions of the sacrificial and active layers SAL and ACL elongated in the second direction D2 may be removed to form second holes H2 on the substrate 100. The second holes H2 may be formed to extend in the second direction D2. Opposite side surfaces of the sacrificial and active layers SAL and ACL may be exposed to the outside by the second holes H2. An upper portion of the substrate 100 may be removed, when the second holes H2 are formed. A portion of the top surface of the substrate 100 may be exposed to the outside by the second holes H2.

As a result of the process described with reference to FIGS. 8, 9A, and 9B, a remaining portion of portions of the sacrificial and active layers SAL and ACL, which are elongated in the second direction D2, may be left on the substrate 100. Portions of the sacrificial and active layers SAL and ACL, which are elongated in the first direction D1, may be disposed at both sides of the remaining portion of the portions elongated in the second direction D2 and may be placed to be mirror-symmetric with respect to the remaining portion of the portions elongated in the second direction D2.

Referring to FIGS. 10 and 11, side surfaces of the sacrificial layers SAL exposed by the second holes H2 may be laterally recessed. Since the side surfaces of the sacrificial layers SAL are recessed, first lateral regions LR1 may be formed. The active layers ACL may not be removed during the formation of the first lateral regions LR1. Due to the first lateral regions LR1, ends of the active layers ACL, which are opposite to each other in the first direction D1, may have a structure protruding or extending in the first direction D1 or the opposite direction thereof, compared with the sacrificial layers SAL.

Referring to FIGS. 10 and 12, a first sacrificial pattern SAP1 may be formed on the active and sacrificial layers ACL and SAL, which are exposed by the second holes H2 and the first lateral regions LR1. For the sake of simplicity, the first sacrificial pattern SAP1 is not illustrated in FIG. 10. The first sacrificial pattern SAP1 may be formed through, for example, an oxidation process. In an embodiment, since the active layers ACL include silicon (Si) and the sacrificial layers SAL include silicon-germanium (SiGe), a silicon oxide layer may be formed by the oxidation process. That is, the first sacrificial pattern SAP1 may include a silicon oxide layer.

The first sacrificial pattern SAP1 may be thicker or wider on the active layers ACL than on the sacrificial layers SAL. In detail, the first sacrificial pattern SAP1 may have an active thickness WA on the active layers ACL and may have an sacrificial thickness WS on the sacrificial layers SAL. The active thickness WA of the first sacrificial pattern SAP1 may be larger than the sacrificial thickness WS of the first sacrificial pattern SAP1. In an embodiment, since the active layers ACL include silicon (Si) and the sacrificial layers SAL include silicon-germanium (SiGe), the first sacrificial pattern SAP1 formed by the oxidation process may have different thicknesses on the active and sacrificial layers ACL and SAL.

Referring to FIGS. 13 and 14, a portion of the first sacrificial pattern SAP1 may be removed. After the removal process, the first sacrificial patterns SAP1 may be left on opposite ends of each of the active layers ACL. One of the first sacrificial patterns SAP1 may be left to cover or overlap the entire top surface of the uppermost one of the active layers ACL in the vertical direction D3. In an embodiment, the removal process may include a first etching process, which is performed to remove a portion of the first sacrificial pattern SAP1 in a horizontal direction (i.e., the first direction D1 or the opposite direction thereof). The first sacrificial pattern SAP1 on the sacrificial layers SAL may be removed during the first etching process, and thus, the side surfaces of the sacrificial layers SAL may be exposed. A relatively thick portion of the first sacrificial pattern SAP1 (i.e., on the active layers ACL) may be left, after the first etching process.

A portion of each of the sacrificial layers SAL, which are laterally exposed through the second holes H2, may be selectively removed. Thus, first inner regions INR1 may be formed between the active layers ACL, which are spaced apart from each other in the vertical direction D3. The first preliminary filling patterns PF1 may also be removed during the removal process. A portion of each of the active layers ACL may be recessed during the removal process. Accordingly, the first recessed top surface 1RU and the first recessed bottom surface 1RL may be formed in each of the active layers ACL. However, due to the remaining portion of the first sacrificial pattern SAP1, the ends of each of the active layers ACL may not be exposed to the removal process and may be protected. That is, the ends of each of the active layers ACL may not be recessed.

Although the sacrificial and active layers SAL and ACL include materials having an etch selectivity, when one of the sacrificial and active layers SAL and ACL is removed in a fabrication process, the other may also be partially removed. Thus, the semiconductor pattern SP may partially have its intended shape after the fabrication process is completed.

According to an embodiment of the present disclosure, an oxidation process may be performed to form the first sacrificial pattern SAP1 having different thicknesses on the sacrificial and active layers SAL and ACL. Thus, as described with reference to FIGS. 13 and 14, the ends of each of the active layers ACL may be protected by a remaining portion of the first sacrificial pattern SAP1. That is, ends of the active layers ACL may be protected without a recessing issue in a subsequent process of selectively removing the sacrificial layers SAL. Thus, a final structure of the semiconductor pattern SP may be formed to have a shape resembling a bar. In other words, it may be possible to realize an ideal shape of the semiconductor pattern SP and to increase a contact stability of the semiconductor pattern SP, and thus, the three-dimensional semiconductor device may be fabricated to have improved electrical and reliability characteristics.

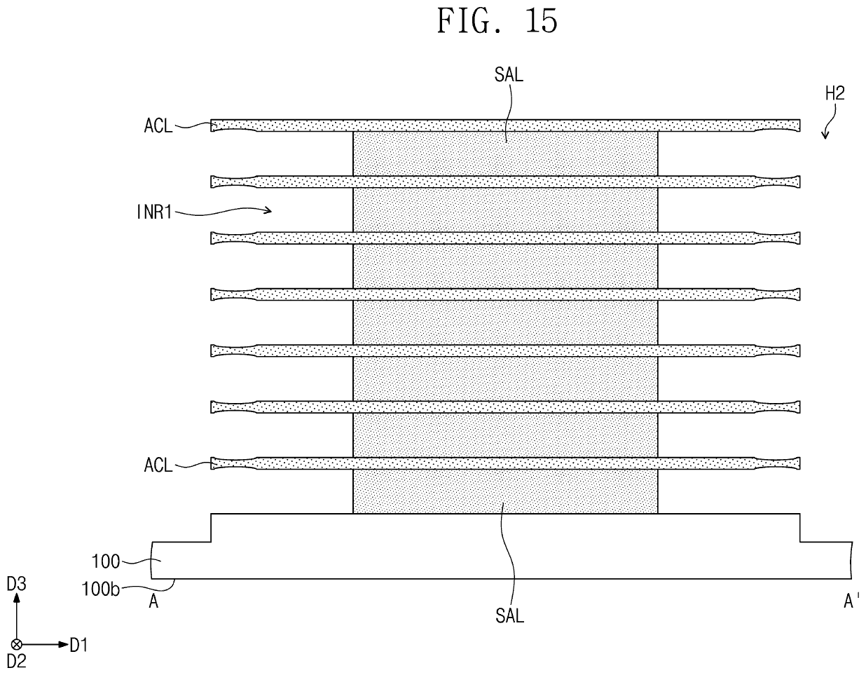

Referring to FIG. 15, the remaining portions of the first sacrificial pattern SAP1 may be removed. Thus, the ends of each of the active layers ACL may be exposed.

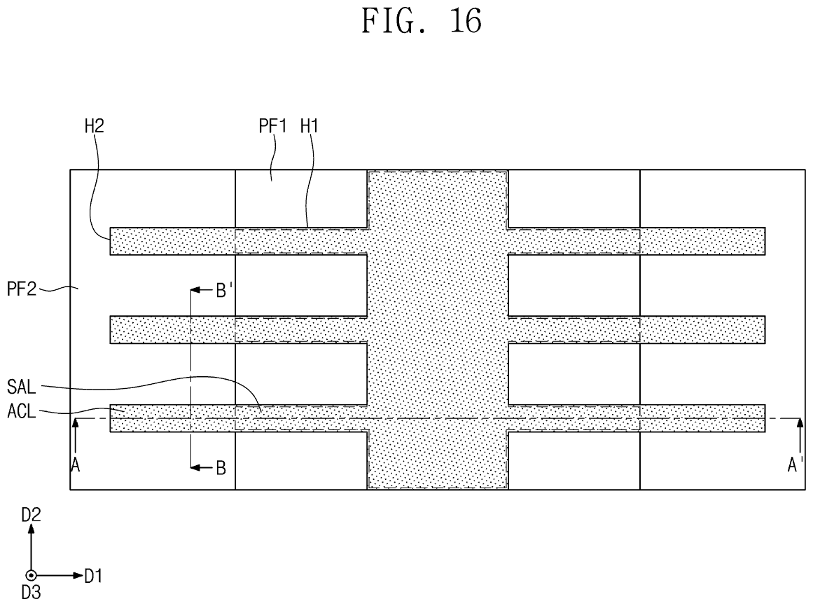

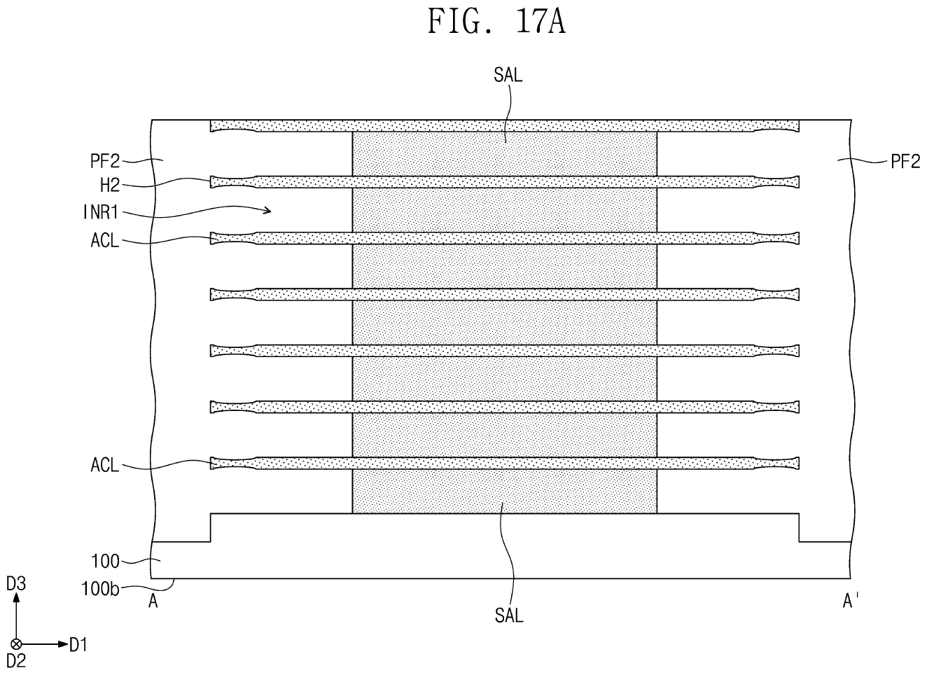

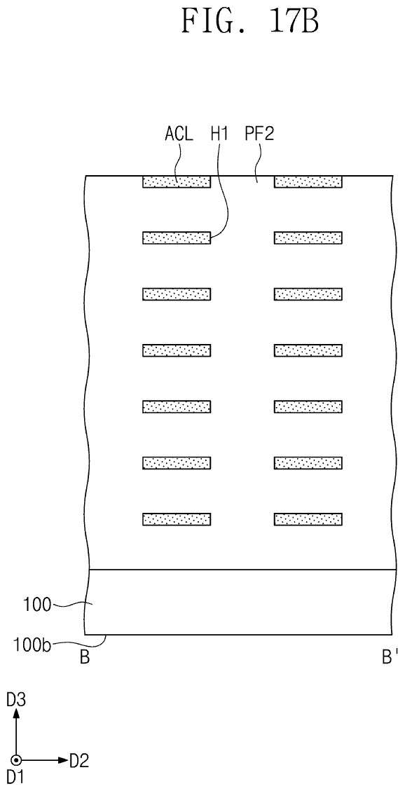

Referring to FIGS. 16, 17A, and 17B, a second preliminary filling pattern PF2 may be formed to at least partially fill the first inner regions INR1, a region, which is formed by partially removing the first preliminary filling patterns PF1, and the second holes H2. The second preliminary filling pattern PF2 may at least partially surround (e.g., extend around) and cover the active layers ACL, which are not vertically overlapped with the sacrificial layers SAL. The second preliminary filling pattern PF2 may include a single or composite layer including an insulating material. In an embodiment, the second preliminary filling pattern PF2 may be formed of or include at least one of silicon oxide or silicon nitride.

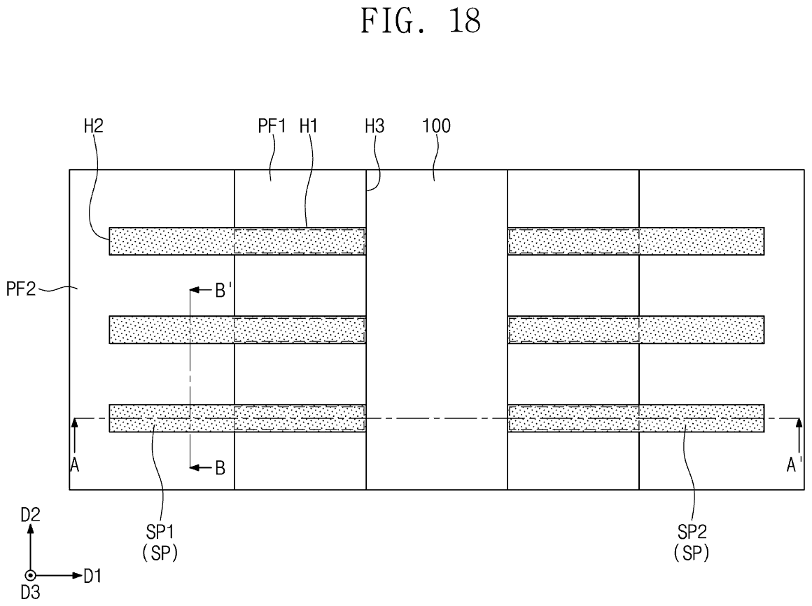

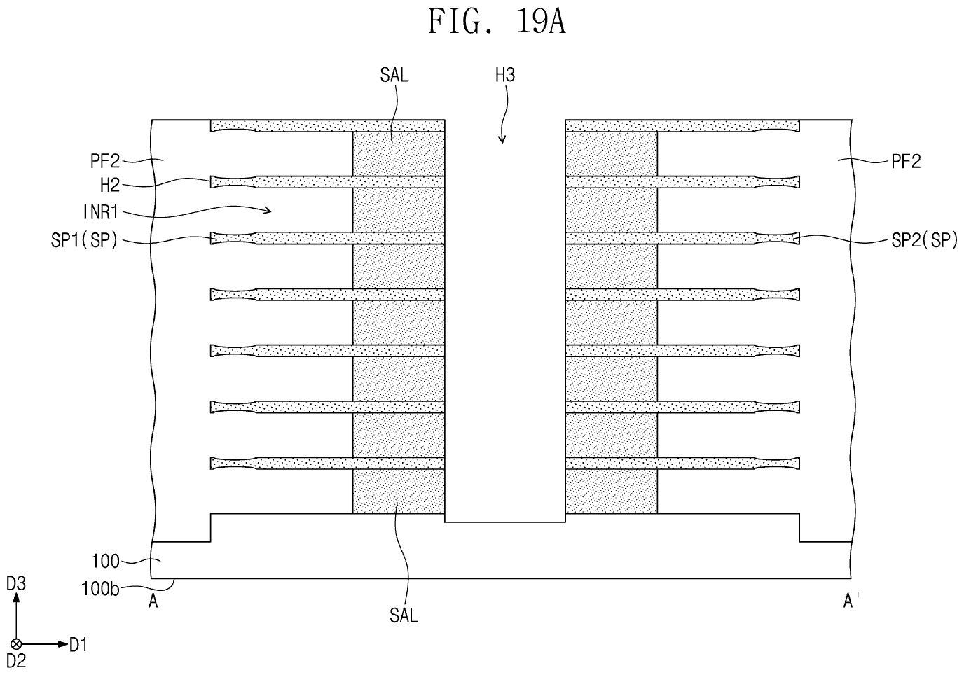

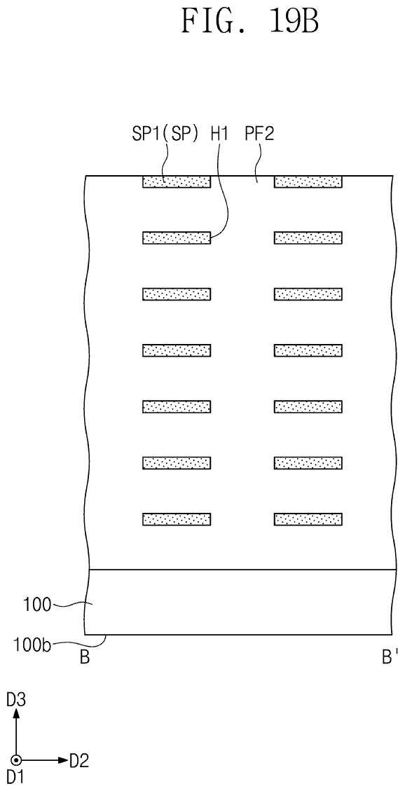

Referring to FIGS. 18, 19A, and 19B, a third hole H3 may be formed on the substrate 100 by removing the remaining portion of portions of the sacrificial and active layers SAL and ACL, which are elongated in the second direction D2. As a result of the formation of the third hole H3, each active layer ACL may be divided into the semiconductor patterns SP, which are spaced apart from each other in the first direction D1. The semiconductor pattern SP may include the first semiconductor pattern SP1 and the second semiconductor pattern SP2, which are spaced apart from each other in the first direction D1. As a result of the formation of the third hole H3, the side surfaces of the sacrificial layers SAL may be exposed to the outside again.

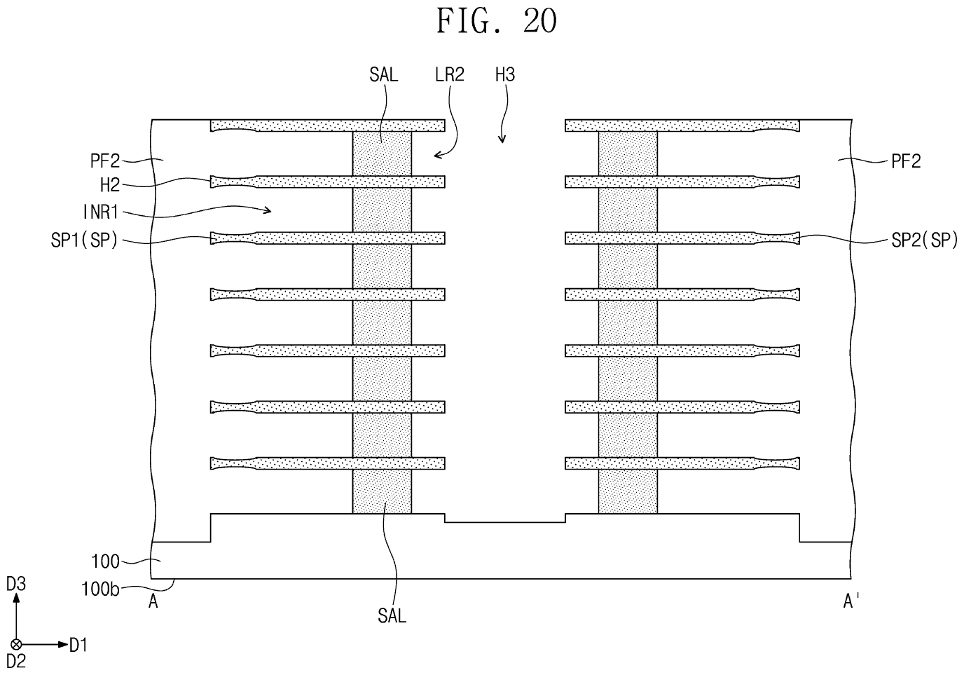

Referring to FIG. 20, the side surfaces of the sacrificial layers SAL exposed by the third hole H3 may be partially removed. As a result of the partial removal of the sacrificial layers SAL, second lateral regions LR2 may be formed. The semiconductor patterns SP may not be removed during the formation of the second lateral regions LR2. Due to the second lateral regions LR2, the first semiconductor patterns SP1 may have a structure protruding or extending in the first direction D1, compared with the sacrificial layers SAL. Due to the second lateral regions LR2, the second semiconductor patterns SP2 may have a structure protruding or extending in the opposite direction of the first direction D1, compared with the sacrificial layers SAL.

Referring to FIGS. 21A and 21B, a second sacrificial pattern SAP2 may be formed on the semiconductor patterns SP and the sacrificial layers SAL exposed by the third hole H3 and the second lateral regions LR2. The formation of the second sacrificial pattern SAP2 may be formed through, for example, an oxidation process. That is, the second sacrificial pattern SAP2 may be formed through substantially the same process as described with reference to FIG. 12.

A thickness of the second sacrificial pattern SAP2 may be larger on the semiconductor patterns SP than on the sacrificial layers SAL. In detail, the second sacrificial pattern SAP2 covering or overlapping the semiconductor patterns SP may have an active thickness WA, and the second sacrificial pattern SAP2 covering or overlapping the sacrificial layers SAL may have a sacrificial thickness WS. The active thickness WA of the second sacrificial pattern SAP2 may be larger than the sacrificial thickness WS of the second sacrificial pattern SAP2. In an embodiment, since the semiconductor patterns SP includes silicon (Si) and the sacrificial layers SAL include silicon-germanium (SiGe), this may result in the thickness difference of the second sacrificial pattern SAP2 formed by the oxidation process.

Referring to FIGS. 22A and 22B, a portion of the second sacrificial pattern SAP2 may be removed. After the removal process, the second sacrificial pattern SAP2 may be left on the end of each of the semiconductor patterns SP. The second sacrificial pattern SAP2 may also be left on the uppermost ones of the semiconductor patterns SP to cover or overlap the entire top surfaces thereof in the vertical direction D3. In an embodiment, the removal process may include a second etching process of removing a portion of the second sacrificial pattern SAP2 in a horizontal direction (i.e., the first direction D1 or the opposite direction thereof). Since the second sacrificial pattern SAP2 on the sacrificial layers SAL is removed through the second etching process, the side surfaces of the sacrificial layers SAL may be exposed. A relatively thick portion of the second sacrificial pattern SAP2 (e.g., on the semiconductor patterns SP) may be left when the second etching process is finished.

The sacrificial layers SAL, which are laterally exposed through the third hole H3, may be removed. Thus, second inner regions INR2 may be formed between the semiconductor patterns SP, which are spaced apart from each other in the vertical direction D3. The first preliminary filling patterns PF1 may be removed during the removal process. The second preliminary filling pattern PF2 may not be removed during the removal process. The second inner regions INR2 may be formed between the semiconductor patterns SP, which are not overlapped with the second preliminary filling pattern PF2. In the removal process, a portion of each of the semiconductor patterns SP may be recessed. Accordingly, the second recessed top surface 2RU and the second recessed bottom surface 2RL may be formed in each of the semiconductor patterns SP. However, the end of each of the semiconductor patterns SP may not be exposed and may be protected by a remaining portion of the second sacrificial pattern SAP2 described above. That is, the end of each of the semiconductor patterns SP may not be recessed.

According to an embodiment of the present disclosure, the end of each of the semiconductor patterns SP may be protected by a remaining portion of the second sacrificial pattern SAP2. That is, the end of each of the semiconductor patterns SP may not be recessed and may be protected in a subsequent process. Thus, a final structure of the semiconductor pattern SP may be formed to have a shape resembling a bar. In other words, it may be possible to realize an ideal shape of the semiconductor pattern SP, and thus, the electrical and reliability characteristics of the three-dimensional semiconductor device may be improved.

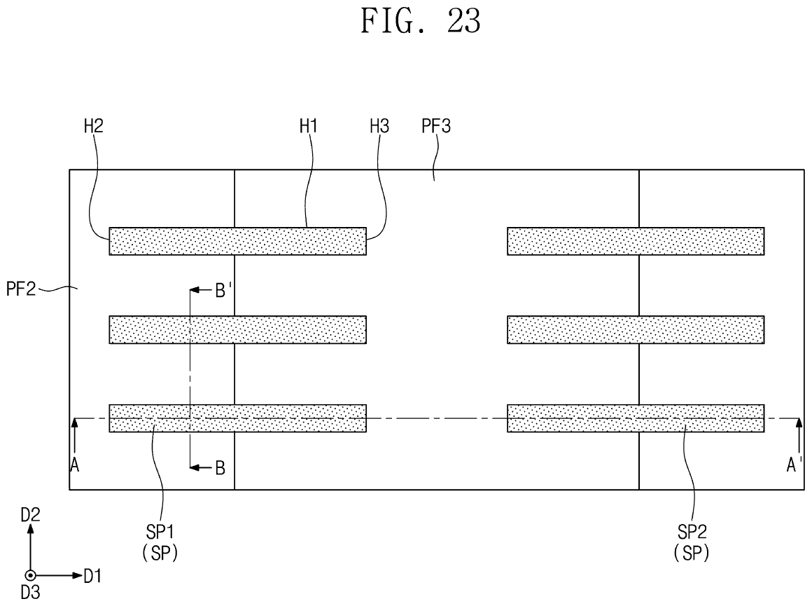

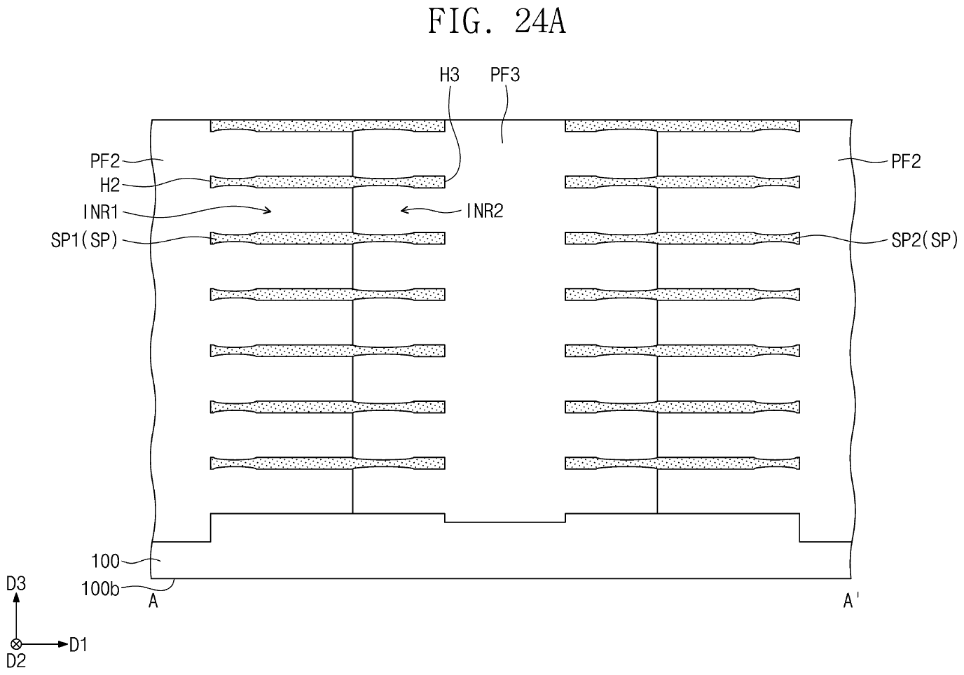

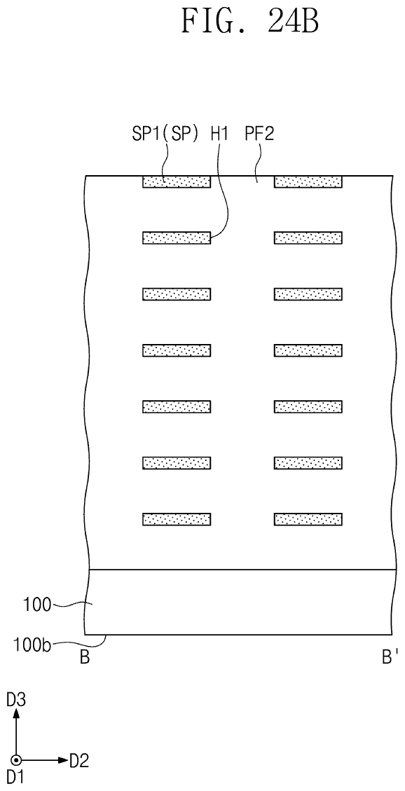

Referring to FIGS. 23, 24A, and 24B, remaining portions of the second sacrificial pattern SAP2 may be removed. Accordingly, the end of each of the semiconductor patterns SP may be exposed.

A third preliminary filling pattern PF3 may be formed to at least partially fill the second inner regions INR2, a region, which is formed by removing the first preliminary filling patterns PF1, and the third hole H3. The third preliminary filling pattern PF3 may include a single or composite layer including an insulating material. In an embodiment, the third preliminary filling pattern PF3 may include at least one of silicon oxide or silicon nitride.

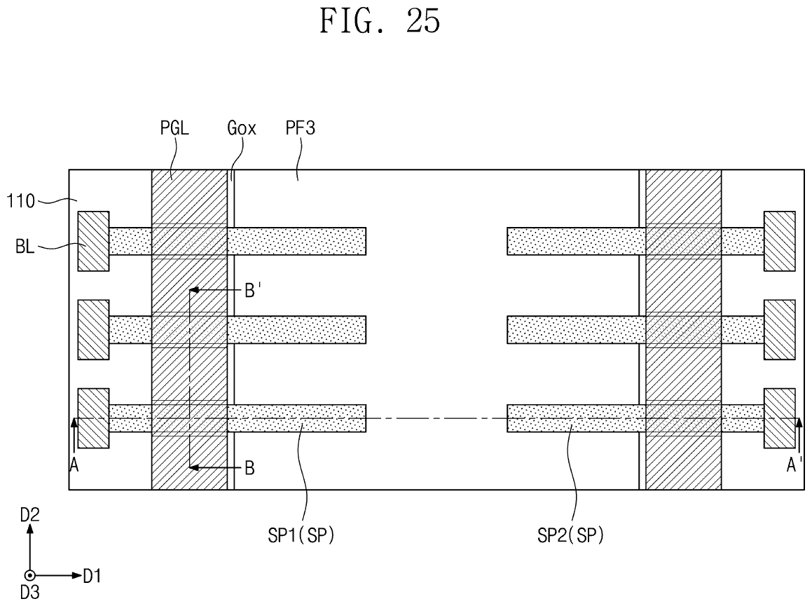

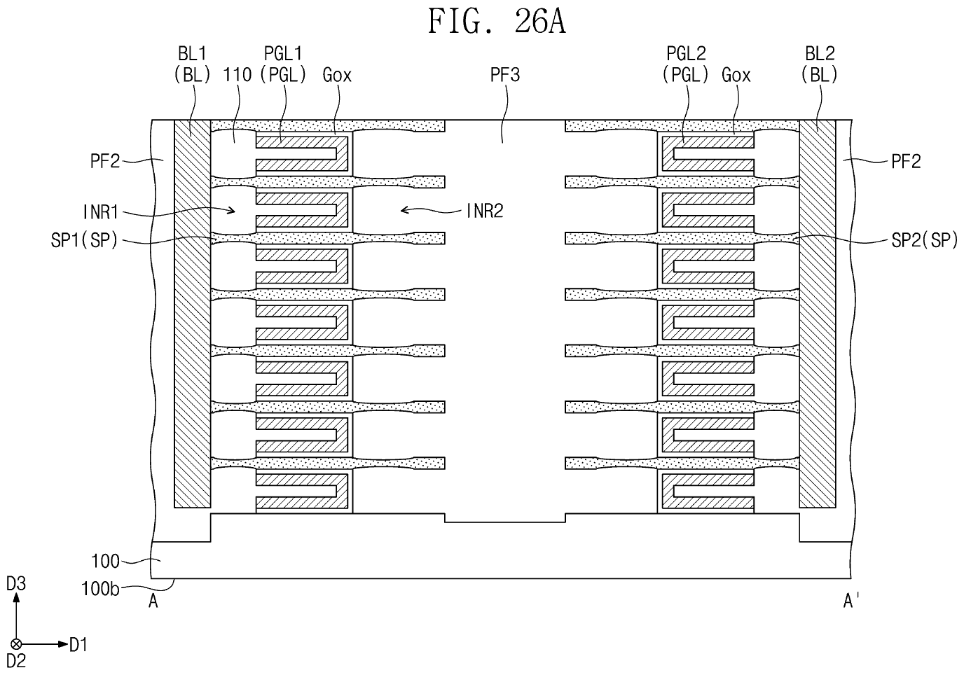

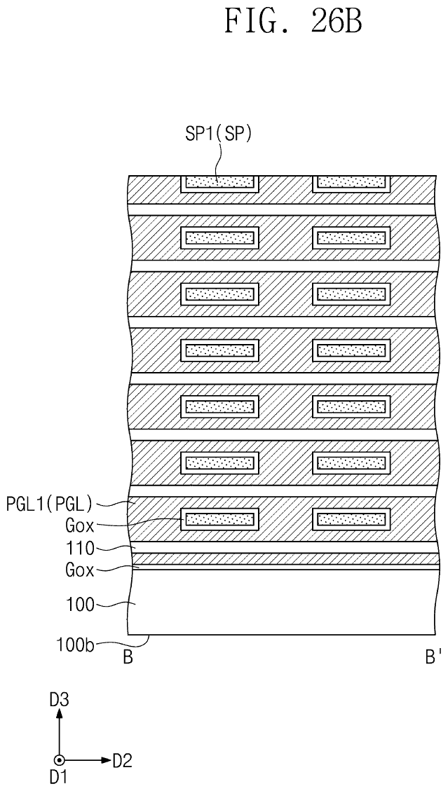

Referring to FIGS. 25, 26A, and 26B, the second preliminary filling pattern PF2 may be removed from a region on the substrate 100. Next, the gate insulating layer Gox and preliminary gate conductive layers PGL1 and PGL2 may be sequentially formed in the first inner regions INR1. The gate insulating layer Gox and the preliminary gate conductive layers PGL1 and PGL2 may be sequentially formed to conformally cover or overlap a portion of the semiconductor pattern SP. The gate insulating layer Gox and the preliminary gate conductive layers PGL1 and PGL2 may be formed to at least partially surround (e.g., extend around) or cover a portion of the semiconductor pattern SP. Each gate insulating layer Gox and each preliminary gate conductive layers PGL1 and PGL2 may be formed to at least partially surround (e.g., extend around) or cover a portion of each of the semiconductor patterns SP, which are spaced apart from each other in the second and third directions D2 and D3. Thereafter, the gapfill insulating pattern 110 may be formed in a region, which is formed by removing the first inner regions INR1 and the second preliminary filling pattern PF2.

The bit lines BL may be formed to penetrate or extend into the gapfill insulating pattern 110 and to be in contact with side surfaces of the semiconductor patterns SP. The bit lines BL may include first bit lines BL1 in contact with the first semiconductor patterns SP1 and second bit lines BL2 in contact with the second semiconductor patterns SP2.

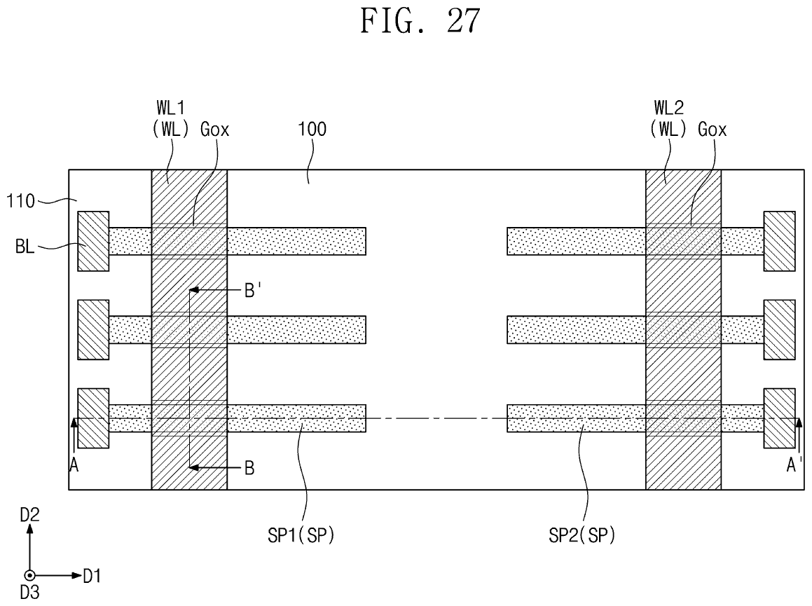

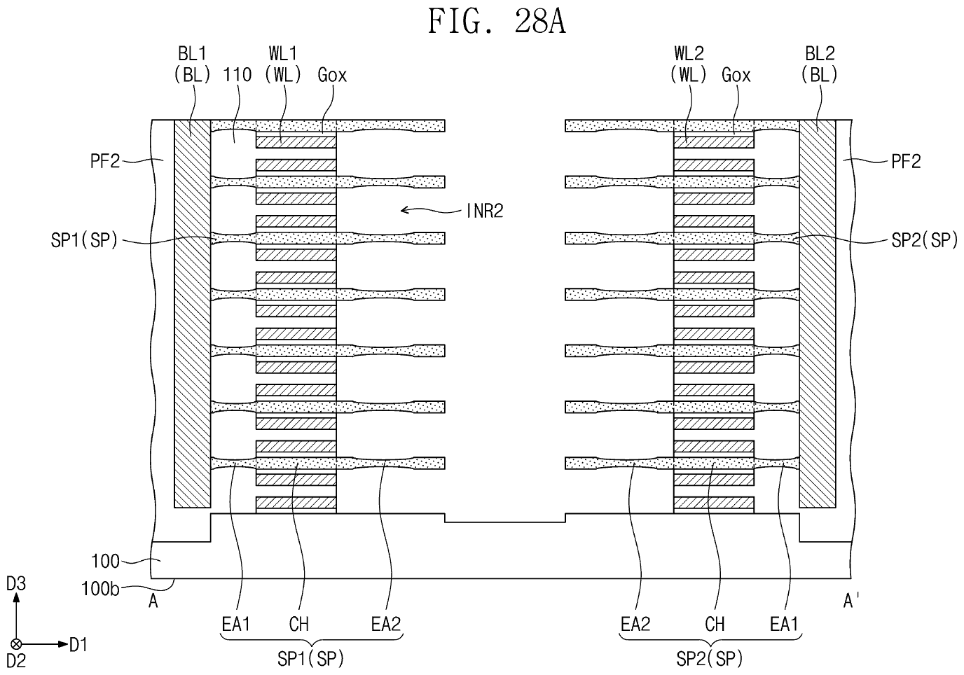

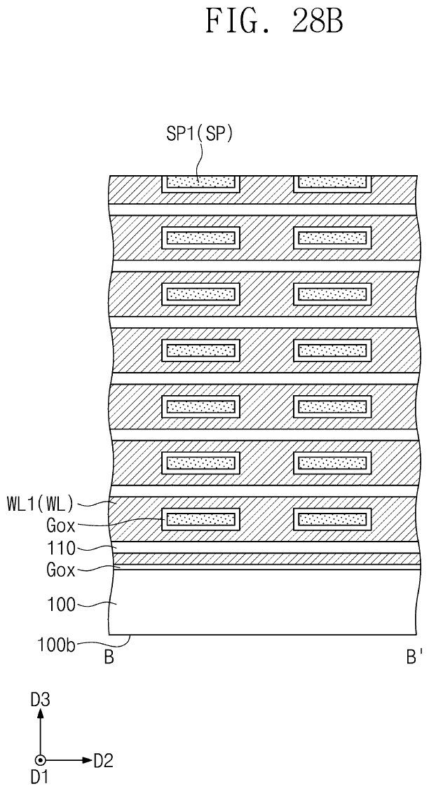

Referring to FIGS. 27, 28A, and 28B, the third preliminary filling pattern PF3 may be removed from a region on the substrate 100. In an embodiment, the removal process may be performed to partially remove the gate insulating layer Gox and the preliminary gate conductive layers PGL1 and PGL2. Accordingly, each gate insulating layer Gox may be divided into a plurality of the gate insulating layers Gox, which are spaced apart from each other in the third direction D3. In addition, each of the preliminary gate conductive layers PGL1 and PGL2 may be divided into a plurality of word lines WL1 and WL2, which are spaced apart from each other in the third direction D3. Each of the gate insulating layers Gox may at least partially enclose a corresponding one of the semiconductor patterns SP. Each of the word lines WL may at least partially enclose a corresponding one of the semiconductor patterns SP and a corresponding one of the gate insulating layers Gox.

During the removal process, the second inner regions INR2 may be exposed to the outside. Side surfaces of the word lines WL may be exposed to the outside by the second inner regions INR2.

The word lines WL may include first word lines WL1 at least partially enclosing the first semiconductor patterns SP1 and second word lines WL2 at least partially enclosing the second semiconductor patterns SP2.

A region of the first semiconductor pattern SP1 enclosed by the first word line WL1 may constitute the channel region CH of the first semiconductor pattern SP1. A region of the second semiconductor pattern SP2 enclosed by the second word line WL2 may constitute the channel region CH of the second semiconductor pattern SP2.

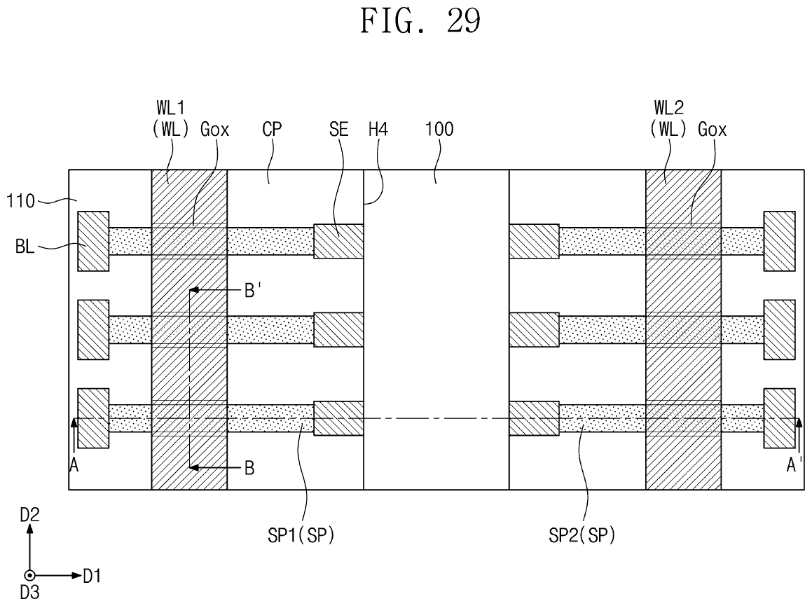

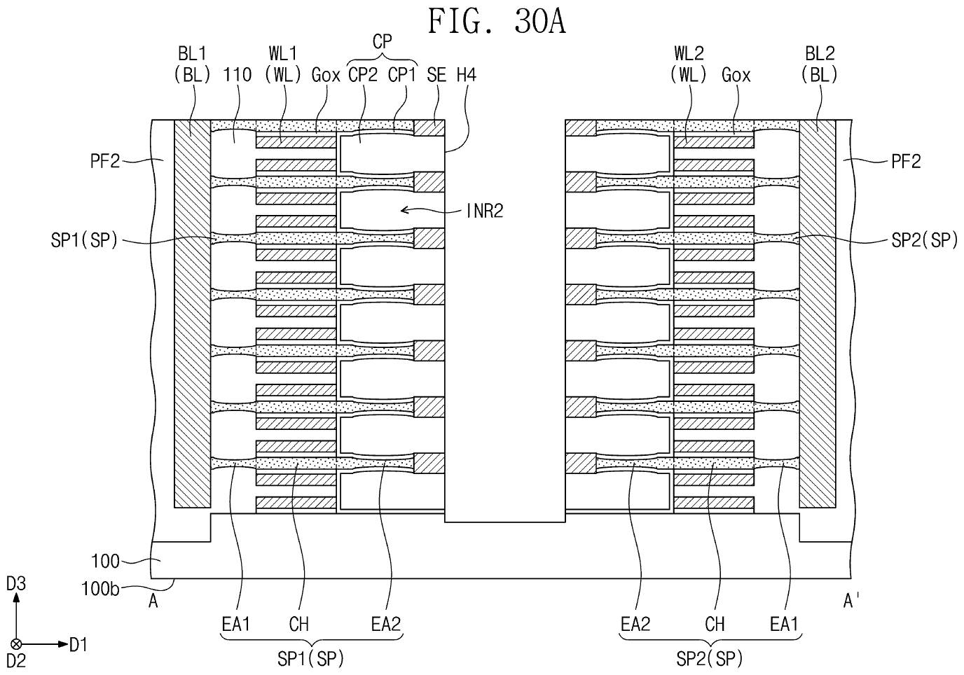

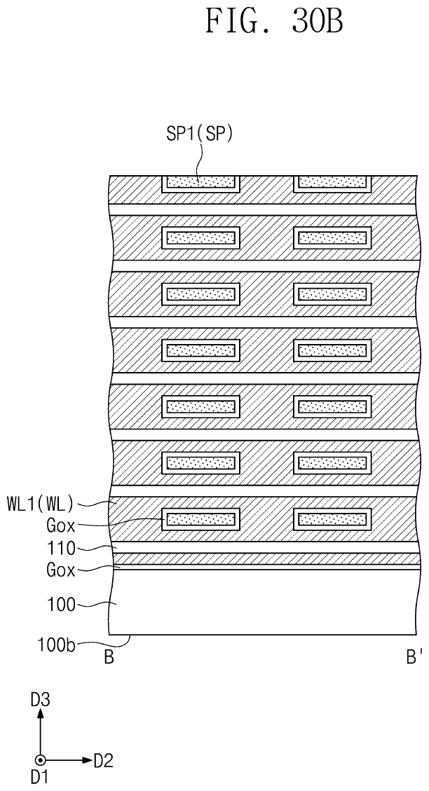

Referring to FIGS. 29, 30A, and 30B, the capping pattern CP may be formed to at least partially fill the second inner regions INR2 and an empty region, which is formed by removing the third preliminary filling pattern PF3. The capping pattern CP may include the first capping pattern CP1, which conformally covers or overlaps the second inner regions INR2 and the second edge portions EA2 of the semiconductor patterns SP, and the second capping pattern CP2, which fills or is in a remaining portion of the second inner regions INR2 and at least partially encloses the second edge portions EA2 of the semiconductor patterns SP.

Thereafter, a portion of the capping pattern CP may be removed to form a fourth hole H4 on the substrate 100. The fourth hole H4 may be formed to extend in the second direction D2. The second edge portions EA2 of the semiconductor patterns SP may be exposed to the outside by the fourth hole H4.

A removal process may be performed on the exposed portion of the second edge portions EA2 of the semiconductor patterns SP through the fourth hole H4. A portion of the first capping pattern CP1 may also be removed during the removal process.

The storage electrodes SE may be formed on the second edge portions EA2 of the semiconductor patterns SP. In an embodiment, the formation of the storage electrodes SE may include forming silicide patterns (not shown) on the second edge portions EA2 of the semiconductor patterns SP and forming the storage electrodes SE through a SEG process using silicide patterns as a seed layer.

Referring back to FIGS. 3, 4, 5A, and 5B, a removal process may be performed on a portion of the second capping pattern CP2. Thus, a side surface of the second capping pattern CP2 may be aligned with a side surface of the second edge portion EA2 of the semiconductor pattern SP. Next, the capacitor dielectric layer CIL may be formed to conformally cover or overlap the storage electrodes SE. The plate electrode PE may be formed to at least partially fill a space between the storage electrodes SE and a remaining portion of the fourth hole H4 described with reference to FIGS. 29, 30A, and 30B. The storage electrode SE, the capacitor dielectric layer CIL, and the plate electrode PE may constitute the data storage pattern DSP. Thereafter, the protection layer PL may be formed to cover or at least partially overlap the cell array structure CS.

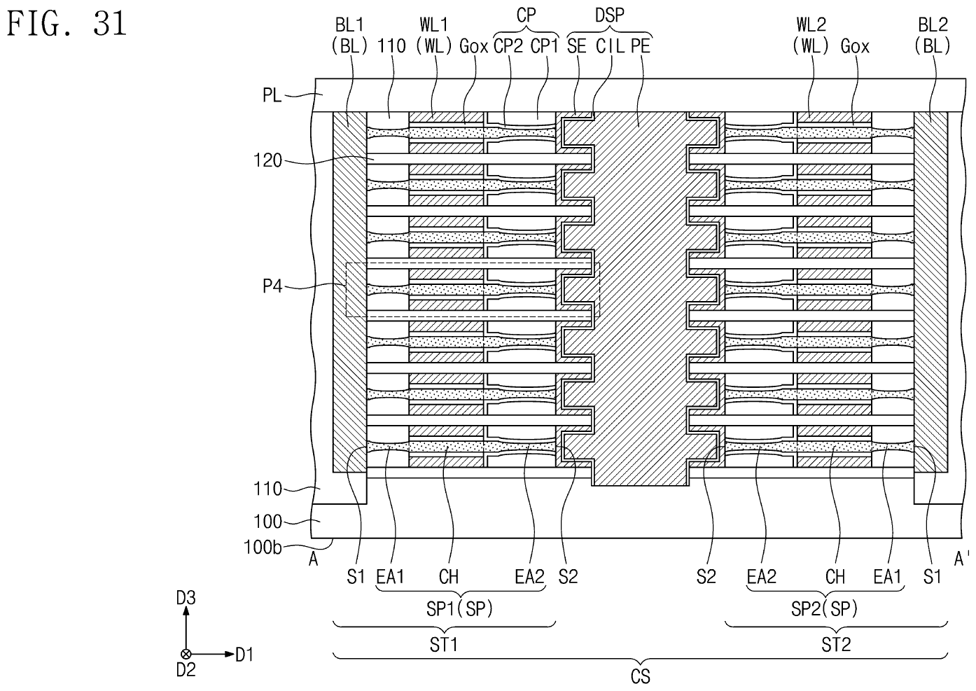

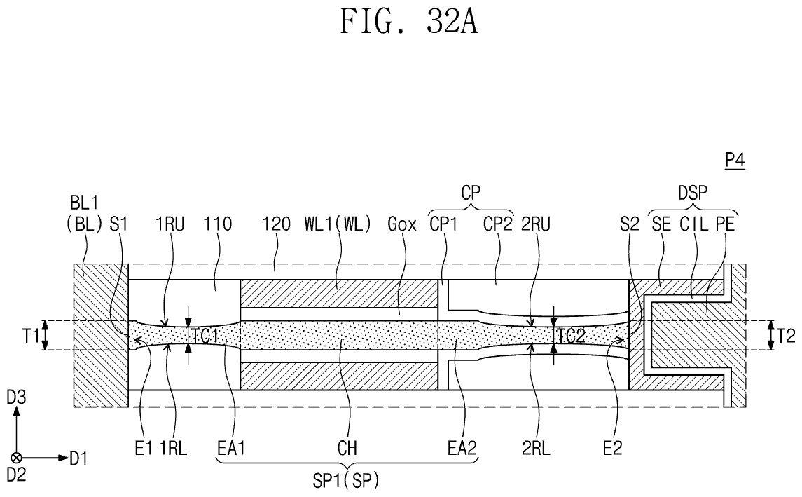

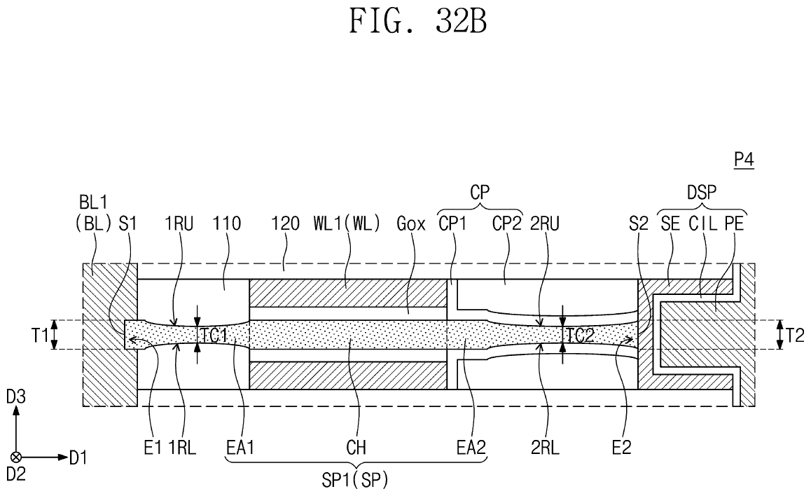

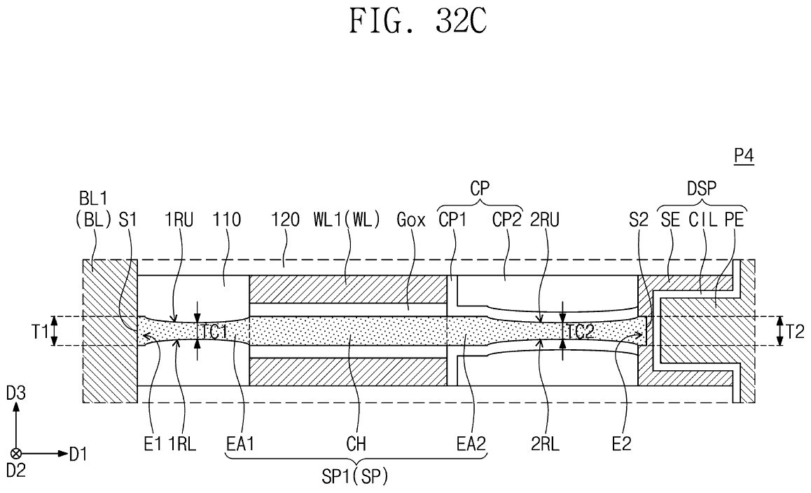

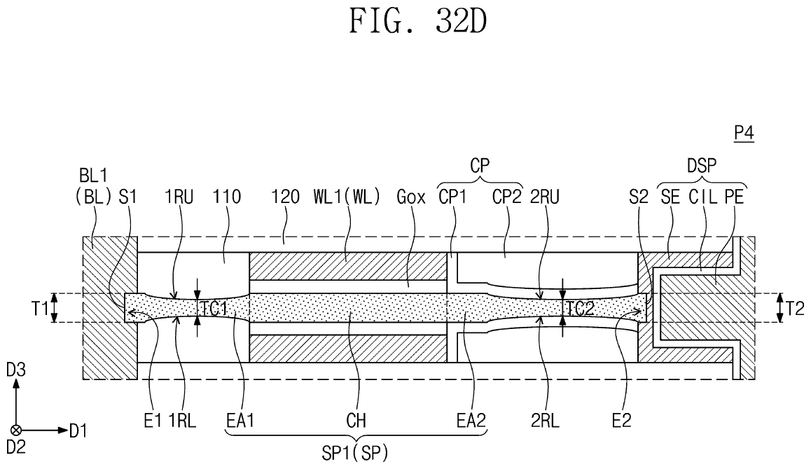

FIG. 31 is a sectional view illustrating a three-dimensional semiconductor device according to an embodiment of the present disclosure, taken along a line A-A′ of FIG. 3. FIGS. 32A to 32D are enlarged views illustrating a portion ‘P4’ of FIG. 31. For concise description, a previously described element may be identified by the same reference number without repeating an overlapping description thereof.

Referring to FIGS. 31 and 32A, each of the first and second stacks ST1 and ST2 may include the semiconductor patterns SP, the word lines WL, the bit lines BL, the first capping patterns CP1, the second capping patterns CP2, the gapfill insulating pattern 110, and an interlayered insulating pattern 120. In an embodiment, the first and second stacks ST1 and ST2 may be provided to have a mirror symmetry with respect to the data storage pattern DSP.

The interlayered insulating pattern 120 may be disposed between the word lines WL, which are adjacent to each other in the vertical direction D3. The word lines WL may be spaced apart from each other in the vertical direction D3 by the interlayered insulating pattern 120. A side surface of the interlayered insulating pattern 120 may be in contact with a side surface of the bit line BL. An opposite side surface of the interlayered insulating pattern 120 may be located at a position beyond the second side surface S2 of the first semiconductor pattern SP1 in the first direction D1. The interlayered insulating pattern 120 may include a single or composite layer including an insulating material.

The data storage pattern DSP may be adjacent to the second side surface S2 of the semiconductor pattern SP. The data storage pattern DSP may include the storage electrode SE, the plate electrode PE, and the capacitor dielectric layer CIL interposed therebetween.

The storage electrode SE may be in contact with the second side surface S2 of the semiconductor pattern SP. The storage electrode SE may have a hollow cup shape. In an embodiment, a plurality of storage electrodes SE may be provided. Each of the storage electrodes SE may be disposed to be in contact with the second side surface S2 of a corresponding one of the semiconductor patterns SP. The storage electrodes SE may be spaced apart from each other in the vertical direction D3. The storage electrodes SE may be disposed between the interlayered insulating patterns 120, respectively, which are vertically adjacent to each other.

The capacitor dielectric layer CIL may be provided to conformally cover or overlap surfaces of the storage electrodes SE. The plate electrode PE may be provided to at least partially fill inner spaces of the storage electrodes SE covered with or overlapped by the capacitor dielectric layer CIL.

Referring to FIG. 32B, the first edge portion EA1 of the semiconductor pattern SP may extend into the bit line BL. The first end E1 of the first edge portion EA1 may extend into the bit line BL. That is, the first side surface S1 may be placed in or extend into the bit line BL. The first end E1 of the first edge portion EA1 may be placed in or extend into the bit line BL. Accordingly, the bit line BL and the semiconductor pattern SP may be electrically connected to each other.

Referring to FIG. 32C, the second edge portion EA2 of the semiconductor pattern SP may extend into the data storage pattern DSP. The second edge portion EA2 of the semiconductor pattern SP may extend into the storage electrode SE. The second end E2 of the second edge portion EA2 may extend into the data storage pattern DSP. The second end E2 of the second edge portion EA2 may extend into the storage electrode SE. That is, the second side surface S2 may be placed in or extend into the data storage pattern DSP. In detail, the second side surface S2 may be placed in or extend into the storage electrode SE. The second end E2 of the second edge portion EA2 may be placed in or extend into the storage electrode SE. Accordingly, the semiconductor pattern SP and the data storage pattern DSP may be electrically connected to each other.

Referring to FIG. 32D, the first edge portion EA1 of the semiconductor pattern SP may extend into the bit line BL, and the second edge portion EA2 may extend into the data storage pattern DSP. The first end E1 of the first edge portion EA1 may extend into the bit line BL, and the second end E2 of the second edge portion EA2 may extend into the data storage pattern DSP. The second end E2 of the second edge portion EA2 may extend into the storage electrode SE. That is, the first side surface S1 may be placed in or extend into the bit line BL, and the second side surface S2 may be placed in or extend into the data storage pattern DSP (e.g., the storage electrode SE). The first end E1 of the first edge portion EA1 may be placed in or extend into the bit line BL. The second end E2 of the second edge portion EA2 may be placed in or extend into the data storage pattern DSP (e.g., the storage electrode SE).

According to an embodiment of the present disclosure, an oxidation process may be performed to form a sacrificial pattern having different thicknesses on sacrificial layers and active layers. Accordingly, ends of each of the active layers may be protected in a subsequent process by a remaining portion of the sacrificial pattern. That is, the ends of the active layers may be protected without a recessing issue in a subsequent process of selectively removing the sacrificial layers. Thus, a final structure of the semiconductor pattern may be formed to have a shape resembling a bar. In other words, it may be possible to realize an ideal shape of the semiconductor pattern and to increase a contact stability of the semiconductor pattern. As a result, the three-dimensional semiconductor device may be fabricated to have improved electrical and reliability characteristics.

While example embodiments of the present disclosure have been particularly shown and described, it will be understood by one of ordinary skill in the art that variations in form and detail may be made therein without departing from the spirit and scope of the attached claims.

What is claimed is:

1. A three-dimensional (3D) semiconductor device, comprising:
a semiconductor pattern that is on a substrate and extends in a first direction parallel to a bottom surface of the substrate, the semiconductor pattern comprising a first edge portion, a second edge portion, and a channel region between the first edge portion and the second edge portion;
a word line that extends around the channel region and extends in a second direction that is parallel to the bottom surface of the substrate and is orthogonal to the first direction; and
a bit line that is on a first side surface of the first edge portion of the semiconductor pattern and extends in a third direction perpendicular to the bottom surface of the substrate,
wherein the first edge portion comprises a first end adjacent to the first side surface, and
wherein a first thickness of the first end in the third direction is greater than a first center thickness of a center portion of the first edge portion in the third direction.

2. The 3D semiconductor device of claim 1, wherein:
the semiconductor pattern comprises a second side surface of the second edge portion,
the first side surface and the second side surface are opposite to each other in the first direction,
the second edge portion has a second end adjacent to the second side surface, and
a second thickness of the second end in the third direction is greater than a second center thickness of a center portion of the second edge portion in the third direction.

3. The 3D semiconductor device of claim 1, further comprising a gapfill insulating pattern that is between the word line and the bit line to at least partially overlap the first edge portion of the semiconductor pattern in the first direction,
wherein the first end of the first edge portion is in the gapfill insulating pattern.

4. The 3D semiconductor device of claim 1, wherein:
the first edge portion of the semiconductor pattern extends into the bit line, and
the first end of the first edge portion extends into the bit line.

5. The 3D semiconductor device of claim 1, wherein:
the semiconductor pattern comprises a second side surface of the second edge portion,
the first side surface and the second side surface are opposite to each other in the first direction, and
the 3D semiconductor device further comprises a data storage pattern on the second side surface of the second edge portion.

6. The 3D semiconductor device of claim 5, wherein the data storage pattern comprises a storage electrode, a plate electrode, and a capacitor dielectric layer between the storage electrode and the plate electrode.

7. The 3D semiconductor device of claim 6, further comprising a capping pattern that is between the word line and the data storage pattern and at least partially overlaps the second edge portion of the semiconductor pattern in the third direction,
wherein the second edge portion has a second end adjacent to the second side surface, and
wherein the second end of the second edge portion is in the capping pattern.

8. The 3D semiconductor device of claim 6, wherein:
the second edge portion of the semiconductor pattern extends into the storage electrode,
the second edge portion has a second end adjacent to the second side surface, and
the second end of the second edge portion extends into the storage electrode.

9. The 3D semiconductor device of claim 1, further comprising a gate insulating layer that is between the semiconductor pattern and the word line and extends around the semiconductor pattern.

10. The 3D semiconductor device of claim 1, wherein the first edge portion has a top surface that is recessed toward the substrate in the third direction.

11. The 3D semiconductor device of claim 1, wherein the second edge portion has a top surface that is recessed toward the substrate in the third direction.

12. The 3D semiconductor device of claim 1, wherein the first edge portion has a bottom surface that is recessed away from the substrate in the third direction.

13. The 3D semiconductor device of claim 1, wherein the second edge portion has a bottom surface that is recessed away from the substrate in the third direction.

14. A three-dimensional (3D) semiconductor device, comprising:
a semiconductor pattern that is on a substrate and extends in a first direction parallel to a bottom surface of the substrate, the semiconductor pattern comprising a first edge portion, a second edge portion, and a channel region between the first edge portion and the second edge portion;
a word line that extends around the channel region and extends in a second direction that is parallel to the bottom surface of the substrate and is orthogonal to the first direction; and
a bit line that is on a first side surface of the first edge portion of the semiconductor pattern and extends in a third direction perpendicular to the bottom surface of the substrate,
wherein the first edge portion has a first recessed top surface that is recessed toward the substrate in the third direction.

15. The 3D semiconductor device of claim 14, wherein the first edge portion has a first recessed bottom surface that is recessed away from the substrate in the third direction.

16. The 3D semiconductor device of claim 14, wherein the second edge portion has a second recessed bottom surface that is recessed away from the substrate in the third direction.

17. The 3D semiconductor device of claim 14, wherein the second edge portion has a second recessed top surface that is recessed toward the substrate in the third direction.

18. A three-dimensional (3D) semiconductor device, comprising:
a first stack and a second stack that are on a substrate and are spaced apart from each other in a first direction parallel to a bottom surface of the substrate; and
a data storage pattern between the first stack and the second stack,
wherein the first stack comprises:
a first semiconductor pattern that is on the substrate and extends in the first direction, the first semiconductor pattern comprising a first edge portion, a second edge portion, and a channel region between the first edge portion and the second edge portion;
a first word line that extends around the channel region and extends in a second direction that is parallel to the bottom surface of the substrate and is orthogonal to the first direction; and
a first bit line that is on a first side surface of the first edge portion of the first semiconductor pattern and extends in a third direction perpendicular to the bottom surface of the substrate,
wherein the first edge portion has a first end adjacent to the first side surface, and
wherein a first thickness of the first end in the third direction is greater than a first center thickness of a center portion of the first edge portion in the third direction.

19. The 3D semiconductor device of claim 18, wherein the second stack comprises:
a second semiconductor pattern that is on the substrate and extends in the first direction;
a second word line that extends around the second semiconductor pattern and extends in the second direction; and
a second bit line that is on a side surface of the second semiconductor pattern and extends in the third direction.

20. The 3D semiconductor device of claim 18, wherein:
the first semiconductor pattern comprises a second side surface of the second edge portion,
the first side surface and the second side surface are opposite to each other in the first direction,
the second edge portion has a second end adjacent to the second side surface, and
a second thickness of the second end in the third direction is larger than a second center thickness of a center portion of the second edge portion in the third direction.
